(19) United States
(12) Patent Application Publication
(10) Pub. No.: US 2025/0294982 A1
(43) Pub. Date: Sep. 18, 2025

(54) DISPLAY APPARATUS

(71) Applicant: Samsung Display Co., LTD., Yongin-si (KR)

(72) Inventors: Taehyun KIM, Yongin-si (KR); Juhoon KANG, Yongin-si (KR); Hayun KANG, Yongin-si (KR); Jieun KIM, Yongin-si (KR)

(21) Appl. No.: 19/031,702

(22) Filed: Jan. 18, 2025

(30) Foreign Application Priority Data
Mar. 13, 2024 (KR) 10-2024-0035423

(51) Int. Cl. H10K 59/131; H10K 59/80

(52) U.S. Cl. CPC H10K 59/131; H10K 59/80516

(57) ABSTRACT

A display apparatus includes a substrate including a main display area, an auxiliary display area outside the main display area, and a peripheral area outside the auxiliary display area, a common voltage supply line in the peripheral area, a connection line contacting the common voltage supply line and having a protrusion protruding into the auxiliary display area, a pixel circuit in the main display area, a main pixel electrode located in the main display area and electrically connected to the pixel circuit, a first auxiliary pixel electrode and a second auxiliary pixel electrode located in the auxiliary display area and electrically connected to each other, an extension line electrically connecting any one of the first auxiliary pixel electrode and the second auxiliary pixel electrode to the pixel circuit, and a driver circuit which at least partially overlaps the auxiliary display area in a plan view.

This application claims priority to Korean Patent Application No. 10-2024-0035423, filed on Mar. 13, 2024, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus including an expanded display area and capable of displaying high-quality images.

### 2. Description of the Related Art

Generally, display apparatuses have a display area where an image is displayed and a peripheral area outside the display area. In these display apparatuses, the area of the display area is increased to relatively reduce the ratio of the peripheral area to the display area.

### SUMMARY

However, it is not easy to display high-quality images on such existing display apparatuses while relatively reducing the area of the peripheral area.

One or more embodiments include a display apparatus including an expanded display area and capable of displaying high-quality images. However, the one or more embodiments are only examples, and the scope of the disclosure is not limited thereto. Additional aspects will be set forth in part in the description which follows and, in part, will be apparent from the description, or may be learned by practice of the presented embodiments of the disclosure.

According to one or more embodiments, a display apparatus includes: a substrate including a main display area, an auxiliary display area outside the main display area, and a peripheral area outside the auxiliary display area, a common voltage supply line located in the peripheral area, a connection line contacting the common voltage supply line and having a protrusion protruding into the auxiliary display area, a pixel circuit located in the main display area, a main pixel electrode located in the main display area and electrically connected to the pixel circuit, a first auxiliary pixel electrode and a second auxiliary pixel electrode located in the auxiliary display area and electrically connected to each other, an extension line electrically connecting any one of the first auxiliary pixel electrode and the second auxiliary pixel electrode to the pixel circuit, and a driver circuit which at least partially overlaps the auxiliary display area when viewed in a direction perpendicular to the substrate.

The display apparatus may further include a plurality of horizontal connection lines extending across the main display area and electrically connected to the protrusion of the connection line.

The display apparatus may further include a contact line located in the auxiliary display area, the contact line may be disposed under the protrusion of the connection line and may contact the protrusion of the connection line, and the plurality of horizontal connection lines may contact the contact line.

The connection line may be directly disposed on the same layer as the first auxiliary pixel electrode, the second auxiliary pixel electrode, and the main pixel electrode, and the plurality of horizontal connection lines may be disposed under the contact line and contact the contact line.

The common voltage supply line may extend along an edge of the substrate, the contact line may extend along at least a portion of the common voltage supply line, and the plurality of horizontal connection lines may extend in a direction crossing a direction in which the contact line extends.

The extension line may be disposed on a first insulating layer covering the contact line, and the first auxiliary pixel electrode, the second auxiliary pixel electrode, the main pixel electrode, and the connection line may be disposed on a second insulating layer covering the extension line.

The extension line may include a transparent conductive layer.

The first auxiliary pixel electrode and the second auxiliary pixel electrode may be integrally formed as a single body.

The driver circuit may be disposed under the first auxiliary pixel electrode and the second auxiliary pixel electrode and under the connection line.

According to one or more embodiments, a display apparatus includes: a substrate including a main display area, an auxiliary display area outside the main display area, and a peripheral area outside the auxiliary display area, a common voltage supply line located in the peripheral area, a connection line electrically connected to the common voltage supply line and located in the peripheral area, an additional connection line having one side contacting the connection line, the additional connection line extending into the auxiliary display area, a pixel circuit located in the main display area, a main pixel electrode located in the main display area and electrically connected to the pixel circuit, a first auxiliary pixel electrode and a second auxiliary pixel electrode located in the auxiliary display area and electrically connected to each other, an extension line electrically connecting any one of the first auxiliary pixel electrode and the second auxiliary pixel electrode to the pixel circuit, and a driver circuit, which at least partially overlaps the auxiliary display area when viewed in a direction perpendicular to the substrate.

The display apparatus may further include a plurality of horizontal connection lines extending across the main display area and electrically connected to the additional connection line.

The display apparatus may further include a contact line located in the auxiliary display area, the contact line may be disposed under the additional connection line and contacting the additional connection line, and the plurality of horizontal connection lines may contact the contact line.

The connection line may be directly disposed on the same layer as the first auxiliary pixel electrode, the second auxiliary pixel electrode, and the main pixel electrode, and the plurality of horizontal connection lines may be disposed under the contact line and contact the contact line.

The common voltage supply line may extend along an edge of the substrate, the contact line may extend along at least a portion of the common voltage supply line, and the plurality of horizontal connection lines may extend in a direction crossing a direction in which the contact line extends.

The extension line may be disposed on a first insulating layer covering the contact line, and the first auxiliary pixel electrode, the second auxiliary pixel electrode, the main pixel electrode, and the connection line may be disposed on a second insulating layer covering the extension line. The first auxiliary pixel electrode and the second auxiliary pixel electrode may be integrally formed as a single body.

The driver circuit may be disposed under the first auxiliary pixel electrode and the second auxiliary pixel electrode and under the connection line.

The driver circuit may be connected to a clock signal line, and the clock signal line may be disposed under the connection line.

The common voltage supply line may extend along an edge of the substrate, and the connection line and the clock signal line may each extend along a portion of the common voltage supply line.

The connection line may contact the common voltage supply line.

The display apparatus may further include an auxiliary connection line which contacts the common voltage supply line and the connection line and electrically connects the common voltage supply line to the connection line.

The auxiliary connection line and the additional connection line may be directly disposed on the same layer.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic cross-sectional view illustrating a portion of a cross-section of the display apparatus, taken along line A-A′ in FIG. 1;

FIGS. 3 and 4 are schematic plan views illustrating a portion of the display apparatus of FIG. 1, the portion corresponding to the cross-section of FIG. 2;

FIG. 5 is an equivalent circuit diagram of a pixel arranged in a main display area of the display apparatus of FIG. 1;

FIG. 6 is a schematic layout diagram illustrating positions of transistors, a capacitor, and the like in pixels arranged in the main display area of the display apparatus of FIG. 1;

FIGS. 7 to 13 are schematic layout diagrams illustrating components of the display apparatus shown in FIG. 6, such as transistors and a capacitor, for each layer;

FIG. 14 is a schematic cross-sectional view illustrating cross-sections of the display apparatus, taken along lines I-I′, II-II′, and III-III′ in FIG. 6;

FIG. 15 is a schematic cross-sectional view illustrating a portion of a display apparatus according to another embodiment;

FIG. 16 is a schematic plan view illustrating a portion of the display apparatus of FIG. 15;

FIG. 17 is a schematic cross-sectional view illustrating a portion of a display apparatus according to an embodiment; and

FIG. 18 is a schematic plan view illustrating a portion of the display apparatus of FIG. 17.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, exemplary embodiments will be described in detail with reference to the accompanying drawings, and in the description with reference to the drawings, the same or corresponding constituents are indicated by the same reference numerals and redundant descriptions thereof are omitted.

It will be understood that when a component, such as a layer, a film, a region, or a plate, is referred to as being “on” another component, the component may be directly on the other component or intervening components may be present therebetween. Sizes of components in the drawings may be exaggerated for convenience of explanation. For example, since sizes and thicknesses of components in the drawings are arbitrarily illustrated for convenience of explanation, the following embodiments are not limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiment, it will be understood that although the terms “first,” “second,” etc. may be used herein to describe various components, these components should not be limited by these terms. These terms are only used to distinguish one component from another.

In the following embodiment, it will be further understood that the terms “include,” “comprise,” and/or “have” used herein specify the presence of stated features or components, but do not preclude the presence or addition of one or more other features or components.

In the specification, the expression such as “A and/or B” may include A, B, or A and B. Furthermore, the expression such as “at least one of A and B” may include A, B, or A and B.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

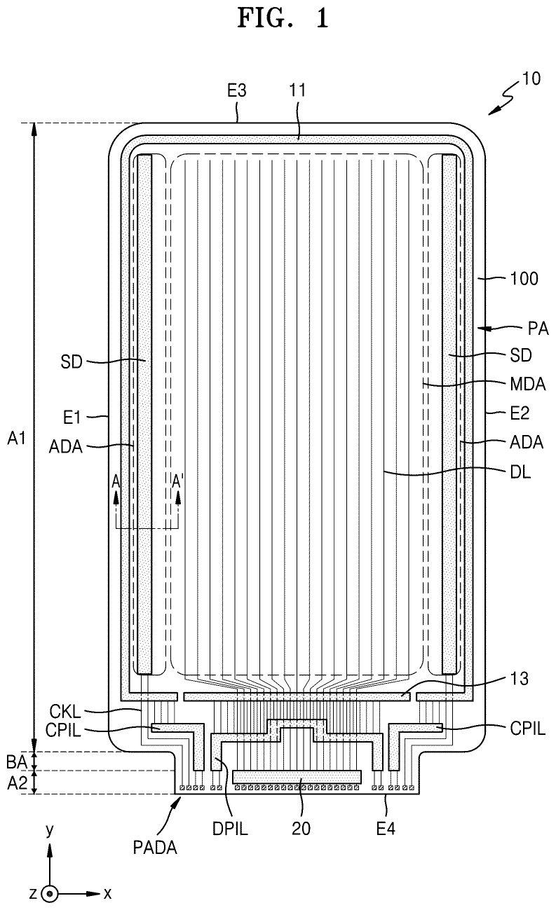

FIG. 1 is a schematic plan view of a display apparatus according to an embodiment. As used herein, the “plan view” is a view in a direction (i.e., z-axis direction) perpendicular to the substrate 100.

The display apparatus according to the present embodiment may include a display panel 10 as shown in FIG. 1. The display apparatus may be any display apparatus that includes the display panel 10. For example, the display apparatus may include various products, such as smartphones, tablet computers, laptop computers, televisions, billboards, vehicle dashboards, or vehicle display apparatuses.

The display panel 10 may have a main display area MDA where a plurality of pixels are located, an auxiliary display area ADA located outside the main display area MDA, and a peripheral area PA located outside the auxiliary display area ADA. Thus, it may be understood that a substrate 100 included in the display apparatus includes the main display area MDA, the auxiliary display area ADA, and the peripheral area PA. For reference, although it is illustrated in FIG. 1 that the main display area MDA and the auxiliary display area ADA are spaced apart from each other, the disclosure is not limited thereto. For another example, an end of the main display area MDA in a direction toward the auxiliary display area ADA may coincide with an end of the auxiliary display area ADA in a direction toward the main display area MDA, and thus, the main display area MDA and the auxiliary display area ADA may form a continuous display area.

At least a portion of a scan driver SD may be located in the auxiliary display area ADA. Although it is illustrated in FIG. 1 that the entire scan driver SD is located within the auxiliary display area ADA, the disclosure is not limited thereto. For another example, a portion of the scan driver SD may be located in the auxiliary display area ADA, and the remaining portion of the scan driver SD may be located in the peripheral area PA.

The peripheral area PA may include a pad area PADA, which is an area on which an electronic element, such as a driving chip 20, or a printed circuit board is electrically attached. In addition, a common voltage input line CPIL, a common voltage supply line 11, a driving voltage input line CPIL, a driving voltage supply line 13, and/or the like may also be arranged in the peripheral area PA. Various wirings or lines, including a clock signal line CKL configure to transmit a clock signal to the scan driver SD, may also pass through the peripheral area PA.

The driving chip 20 may include an integrated circuit that drives the display panel 10. The integrated circuit may be a data driving integrated circuit that generates a data signal. However, the disclosure is not limited thereto. The substrate 100 may have a first edge E1 and a second edge E2, which extend approximately in a first direction (the y-axis direction) and face each other, and may also have a third edge E3 and a fourth edge E4, which extend approximately in a second direction (the x-axis direction) crossing the first direction and may be considered to connect the first edge E1 and the second edge E2 to each other. The driving chip 20 may be mounted in the peripheral area PA so that the driving chip 20 is adjacent to the fourth edge E4 of the substrate 100.

For reference, FIG. 1 may be understood as a plan view showing the substrate 100 and the like during the process of manufacturing the display panel 10. In an electronic apparatus, such as a final display apparatus or a smartphone including a display apparatus, a portion of a substrate may be bent to reduce the area of the peripheral area PA recognized by a user. For example, the peripheral area PA may include a bending area BA, and the bending area BA may be between the pad area PADA and the main display area MDA. In this case, the substrate 100 may be bent in the bending area BA so that a first area A1 located at one side of the bending area BA overlaps a second area A2 located at the other side of the bending area BA.

For example, the substrate 100 may be bent in the bending area BA, and thus, at least a portion of the second area A2 where the pad area PADA is located may overlap the first area A1 where the main display area MDA is located. In this case, a bending direction is set such that the pad area PADA is located behind the main display area MDA, etc. Accordingly, the user perceives the main display area MDA as taking up most of the display apparatus. The driving chip 20 is mounted on the same surface as a display surface of the main display area MDA, but when the display panel 10 is bent in the bending area BA, the driving chip 20 may be located in a direction toward the rear of the main display area MDA.

The substrate 100 may include various materials that are flexible or bendable. For example, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may have a multi-layered structure including two layers and a barrier layer therebetween, each of the two layers may include polymer resin, and the barrier layer may include an inorganic material, such as silicon oxide, silicon nitride, and silicon oxynitride, and various modifications may be made. Furthermore, when the substrate 100 is not bent, the substrate 100 may include glass or the like.

The main display area MDA may have an overall shape similar to a rectangle or square. Accordingly, the substrate 100 may also have an overall shape similar to a rectangle or square. In another embodiment, the main display area MDA may have a circular, oval, or polygonal shape.

As described above, the substrate 100 may have the first edge E1 and the second edge E2, which extend approximately in the first direction (the y-axis direction) and face each other, and may also have the third edge E3 and the fourth edge E4, which extend approximately in the second direction (the x-axis direction) crossing the first direction and may be considered to connect the first edge E1 and the second edge E2 to each other. The pad area PADA may be adjacent to the fourth edge E4 of the peripheral area PA of the substrate 100. In another embodiment, the substrate 100 may have bends between the first edge E1 and the fourth edge E4 and between the second edge E2 and the fourth edge E4, and thus, the substrate 100 and the like in the bending area BA may be easily bent. Accordingly, as shown in FIG. 1, the width of the substrate 100 in the second area A2 in the second direction (the x-axis direction) may be less than the width of the substrate 100 in the first area A1 in the second direction (the x-axis direction).

Although an organic light-emitting display apparatus is hereinafter described as an example of the display apparatus according to an embodiment, the display apparatus of the disclosure is not limited thereto. In another embodiment, the display apparatus of the disclosure may include a display apparatus, such as an inorganic light-emitting display apparatus (an inorganic light-emitting display or an inorganic electroluminescent (EL) display) or a quantum dot light-emitting display. For example, an emission layer of the display element included in the display apparatus may include an organic material or an inorganic material. In addition, the display apparatus may have an emission layer and quantum dots in a path of light emitted from the emission layer.

A plurality of pixels may be in the main display area MDA. Each of the pixels refers to a sub-pixel and may include a display element, such as an organic light-emitting diode, and a pixel circuit electrically connected to the display element. The pixel may emit, for example, red, green, blue, or white light. The pixel may be electrically connected to external circuits arranged in the peripheral area PA. The scan driver SD, the common voltage supply line 11, the driving voltage supply line 13, and the like may be arranged in the peripheral area PA.

The scan driver SD may extend along the first edge E1 of the substrate 100. The scan driver SD may provide a scan signal to pixels through a scan line (not shown) extending in the second direction (the x-axis direction) into the main display area MDA. However, the scan driver SD may also be located along the second edge E2 of the substrate 100. In this case, some of the pixels arranged in the main display area MDA may be electrically connected to a scan driver SD near the first edge E1, and the rest may be electrically connected to a scan driver SD near the second edge E2. Alternatively, an emission control driver rather than the scan driver SD may be located near the second edge E2 of the substrate 100, and an emission control signal and the like may be provided to a pixel through an emission control line (not shown) and the like substantially parallel to the scan line.

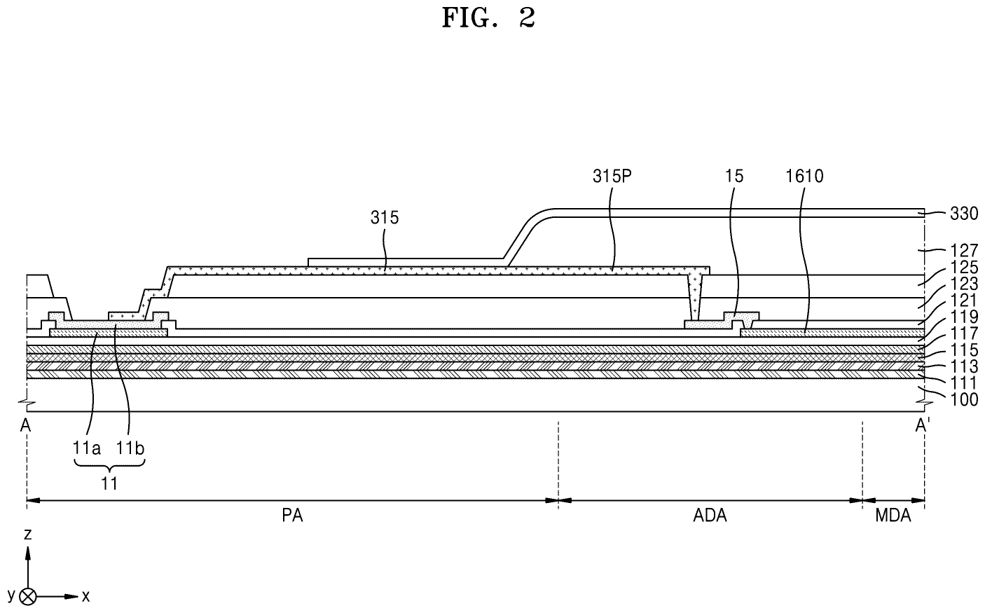

A plurality of pads may be located in the pad area PADA of the display panel 10. The plurality of pads may be exposed without being covered by an insulating layer and be electrically connected to a printed circuit board (not shown). That is, pads of the printed circuit board may be electrically connected to the plurality of pads of the display panel 10. The printed circuit board transmits signals or power from a controller to the display panel 10. Control signal generated by the controller may be transmitted to the driving chip 20, the scan driver SD, and the like through the printed circuit board. In addition, the controller may provide a common voltage ELVSS to the common voltage supply line 11 through the common voltage input line CPIL and thus provide the common voltage ELVSS to a common electrode 330 (see FIG. 2) of an organic light-emitting element located in the main display area MDA and the auxiliary display area ADA. In addition, the controller may provide a driving voltage ELVDD to the driving voltage supply line 13 through the driving voltage input line DPIL and thus provide the driving voltage ELVDD to pixel circuits located within the main display area MDA through a driving voltage line (not shown) extending from the driving voltage supply line 13 into the main display area MDA in the first direction (the y-axis direction). For reference, the common voltage supply line 11 has a loop shape with one side open in the fourth edge E4 direction, and extends along the first edge E1, third edge E3, and second edge E2. It can have a given shape.

The controller may generate a data signal, and the generated data signal may be transmitted to a pixel through the driving chip 20 and the data line DL. It is illustrated in FIG. 1 that the clock signal line CKL receives a clock signal through a pad and transmits the clock signal to the scan driver SD. However, unlike this, the clock signal line CKL may receive a clock signal from the driving chip 20 and transmit the clock signal to the scan driver SD in another embodiment.

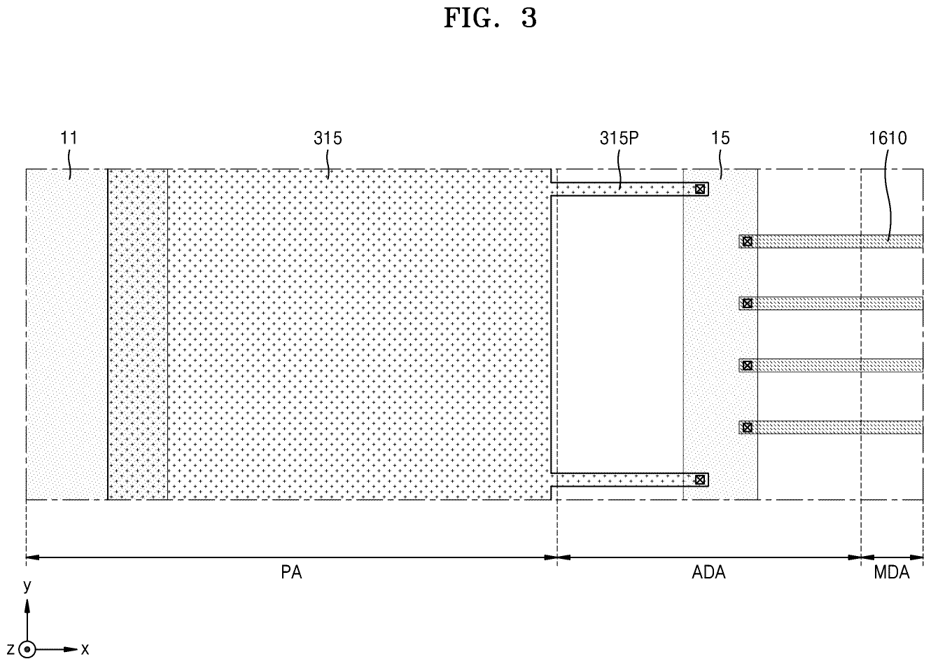

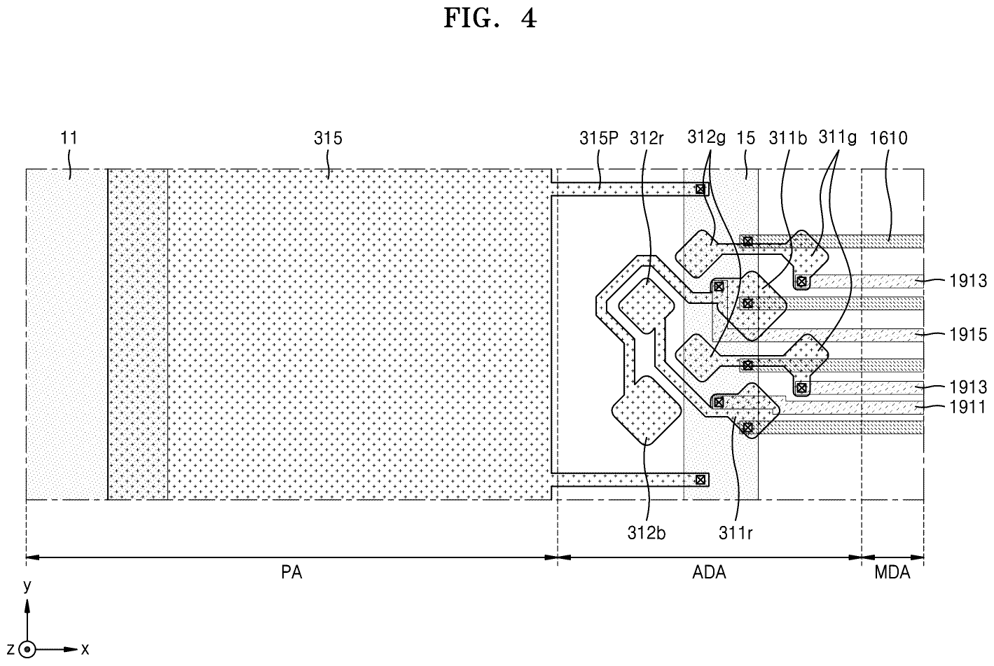

Hereinafter, with reference to FIGS. 2, 3, and 4, it will be described that a common voltage is provided from the common voltage supply line 11 to the common electrode 330 of the organic light-emitting element located in the main display area MDA and the auxiliary display area ADA. FIG. 2 is a schematic cross-sectional view illustrating a portion of a cross-section of the display apparatus, taken along line A-A′ in FIG. 1, and FIGS. 3 and 4 are schematic plan views illustrating a portion of the display apparatus of FIG. 1, the portion corresponding to the cross-section of FIG. 2. For reference, FIG. 4 shows first auxiliary pixel electrodes, second auxiliary pixel electrodes, and extension lines omitted in FIG. 3. In FIG. 2, a thin-film transistor and/or a capacitor included in the scan driver SD are omitted for convenience.

As shown in FIG. 2, the common voltage supply line 11 located in the peripheral area PA may include a first common voltage supply line 11a and a second common voltage supply line 11b that are in contact with each other. The first common voltage supply line 11a may be disposed on a second interlayer-insulating layer 119. A third interlayer-insulating layer 121 may cover the first common voltage supply line 11a and may define an opening that exposes a portion of the upper surface of the first common voltage supply line 11a. Accordingly, the second common voltage supply line 11b disposed on the third interlayer-insulating layer 121 may contact the first common voltage supply line 11a. The first common voltage supply line 11a may be directly formed on the same layer as, of the same material as, and simultaneously with a first connection electrode layer 1600, which is described below, when the first connection electrode layer 1600 is formed. In addition, the second common voltage supply line 11b may be directly formed on the same layer as, of the same material as, and simultaneously with a second connection electrode layer 1800, which is described below, when the second connection electrode layer 1800 is formed.

A connection line 315 may have a shape extending along the common voltage supply line 11 and may contact the common voltage supply line 11. A fourth interlayer-insulating layer 123 may cover the second common voltage supply line 11b and may define an opening therein exposing a portion of the upper surface of the second common voltage supply line 11b, and a planarization layer 125 on the fourth interlayer-insulating layer 123 may also define an opening therein so that a portion of the upper surface of the second common voltage supply line 11b is exposed. The connection line 315 disposed on the planarization layer 125 may contact the upper surface of the second common voltage supply line 11b exposed through these openings.

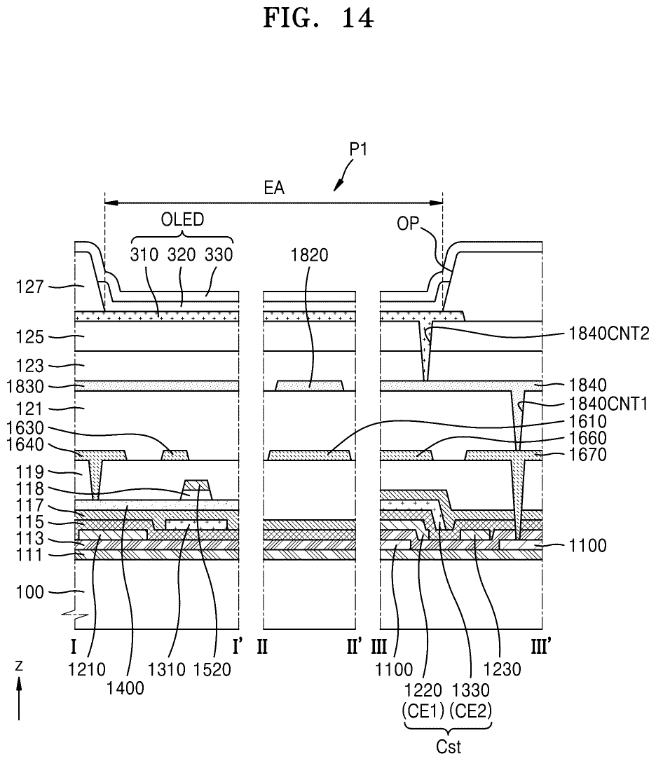

As shown in FIGS. 2, 3, and 4, most of the connection line 315 may be located within the peripheral area PA and may have a protrusion 315P protruding into the auxiliary display area ADA. The connection line 315 may be directly formed on the same layer as, of the same material as, and simultaneously with a main pixel electrode 310 (see FIG. 14), first auxiliary pixel electrodes 311r, 311g, and 311b, and second auxiliary pixel electrodes 312r, 312g, and 312b, which are described below, when the main pixel electrode 310, the first auxiliary pixel electrodes 311r, 311g, and 311b, and the second auxiliary pixel electrodes 312r, 312g, and 312b are formed. Accordingly, the connection line 315 may be directly disposed on the same layer (i.e., the planarization layer 125) as the main pixel electrode 310, the first auxiliary pixel electrodes 311r, 311g, and 311b, and the second auxiliary pixel electrodes 312r, 312g, 312b. Please note that elements with the same hatching in the drawings are directly disposed on a same layer and formed of a same material.

A pixel-defining layer 127 may cover a portion of the connection line 315 and expose a portion of the upper surface of the connection line 315. The common electrode 330 of the organic light-emitting element located in the main display area MDA and the auxiliary display area ADA may contact the connection line 315 outside the pixel-defining layer 127 and thus be electrically connected to the common voltage supply line 11.

A plurality of horizontal connection lines 1610 starting from the auxiliary display area ADA and extending in the second direction (the x-axis direction) to cross the main display area MDA may be disposed on the second interlayer-insulating layer 119. Each of the plurality of horizontal connection lines 1610 may be electrically connected to the protrusion 315P of the connection line 315. The plurality of horizontal connection lines 1610 may be directly formed on the same layer as, of the same material as, and simultaneously with the first connection electrode layer 1600, which is described below, when the first connection electrode layer 1600 is formed.

It is illustrated in FIGS. 2 to 4 that a contact line 15 disposed on the third interlayer-insulating layer 121 located in the auxiliary display area ADA and covering the horizontal connection lines 1610 contacts the horizontal connection lines 1610 through contact holes defined in the third interlayer-insulating layer 121. In addition, it is illustrated in FIGS. 2 to 4 that the protrusion 315P of the connection line 315 contacts the contact line 15 through a contact hole defined in the fourth interlayer-insulating layer 123 and the planarization layer 125 and thus each of the plurality of horizontal connection lines 1610 is electrically connected to the protrusion 315P of the connection line 315. Accordingly, the plurality of horizontal connection lines 1610 may be electrically connected to the common voltage supply line 11. For reference, the contact line 15, like the connection line 315, may have a shape extending along at least a portion of the common voltage supply line 11. The contact line 15 may be directly formed on the same layer as, of the same material as, and simultaneously with the second connection electrode layer 1800, which is described below, when the second connection electrode layer 1800 is formed.

FIGS. 2 to 4 show an area near the first edge E1 in the display apparatus of FIG. 1. However, an area near the second edge E2 in the display apparatus of FIG. 1 may also have the same configuration as shown in FIGS. 2 to 4. The area near the second edge E2 in the display apparatus of FIG. 1 may have a symmetrical shape with the area near the first edge E1 in the display apparatus of FIG. 1 with respect to the center of the main display area MDA.

Accordingly, one end (in a −x direction) of each of the plurality of horizontal connection lines 1610 extending in the second direction (the x-axis direction) to cross the main display area MDA may be electrically connected to a portion of the common voltage supply line 11 near the first edge E1, and the other end (in a +x direction) of each of the plurality of horizontal connection lines 1610 may be electrically connected to a portion of the common voltage supply line 11 near the second edge E2. Accordingly, the occurrence of a voltage drop (IR drop) in the common voltage supply line 11 may be effectively prevented or reduced. As a result, high-quality images may be displayed in the main display area MDA and/or the auxiliary display area ADA.

As described below, a pixel circuit and a main pixel electrode 310 electrically connected to the pixel circuit are located in the main display area MDA. Because the main pixel electrode 310 is located above the pixel circuit electrically connected thereto, when viewed in a direction (the z-axis direction) perpendicular to the substrate 100 (i.e., in a plan view), the main pixel electrode 310 may overlap the pixel circuit electrically connected thereto. Through the pixel circuit, an electrical signal may be applied to the main pixel electrode 310, allowing light to be emitted from the emission layer on the main pixel electrode 310.

In the auxiliary display area ADA, a first auxiliary pixel electrode and a second auxiliary pixel electrode, which are electrically connected to each other, are located, as shown in FIG. 4. The first auxiliary pixel electrode and the second auxiliary pixel electrode may be directly formed on the same layer as, of the same material as, and simultaneously with the main pixel electrode 310 when the main pixel electrode 310 is formed. It is illustrated in FIG. 4 that a first auxiliary pixel electrode 311r for red and a second auxiliary pixel electrode 312r for red, which are electrically connected to each other, a first auxiliary pixel electrode 311g for green and a second auxiliary pixel electrode 312g for green, which are electrically connected to each other, and a first auxiliary pixel electrode 311b for blue and a second auxiliary pixel electrode 312b for blue, which are electrically connected to each other, are located in the auxiliary display area ADA. The first auxiliary pixel electrode and the second auxiliary pixel electrode that are electrically connected to each other may be integrally formed as a single body.

Unlike the main pixel electrode 310, no pixel circuit is disposed under the first and second auxiliary pixel electrodes. The first auxiliary pixel electrode and the second auxiliary pixel electrode may be electrically connected, by an extension line, to a corresponding pixel circuit among the pixel circuits located in the main display area MDA. It is illustrated in FIG. 4 that the first auxiliary pixel electrode 311r for red and the second auxiliary pixel electrode 312r for red are electrically connected to an extension line 1911, the first auxiliary pixel electrode 311g for green and the second auxiliary pixel electrode 312g for green are electrically connected to an extension line 1913, and the first auxiliary pixel electrode 311b for blue and the second auxiliary pixel electrode 312b for blue are electrically connected to an extension line 1915.

The extension lines 1911, 1913, and 1915 may be located between the fourth interlayer-insulating layer 123 and the planarization layer 125. Accordingly, the first auxiliary pixel electrode and the second auxiliary pixel electrode disposed on the planarization layer 125 may contact a corresponding extension line through a contact hole defined in the planarization layer 125. It is illustrated in FIG. 4 that the first auxiliary pixel electrode 311r for red is connected to the extension line 1911 thereunder through a contact hole, the first auxiliary pixel electrode 311g for green is connected to the extension line 1913 thereunder through a contact hole, and the first auxiliary pixel electrode 311b for blue is connected to the extension line 1915 thereunder through a contact hole.

The extension line 1911 electrically connected to the first auxiliary pixel electrode 311r for red and the second auxiliary pixel electrode 312r for red may be electrically connected to a pixel circuit disposed under a main pixel electrode for red adjacent to the auxiliary display area ADA from among the main pixel electrodes 310 located in the main display area MDA. That is, the first auxiliary pixel electrode 311r for red, the second auxiliary pixel electrode 312r for red, and the main pixel electrode for red may be electrically connected to the same pixel circuit. Accordingly, a pixel including the first auxiliary pixel electrode 311r for red and a pixel including the second auxiliary pixel electrode 312r for red may emit light in the same manner as a pixel including the main pixel electrode for red. That is, the pixel including the first auxiliary pixel electrode 311r for red and the pixel including the second auxiliary pixel electrode 312r for red may be ‘copy pixels’ of the pixel including the main pixel electrode for red.

Similarly, the extension line 1913 electrically connected to the first auxiliary pixel electrode 311g for green and the second auxiliary pixel electrode 312g for green may be electrically connected to a pixel circuit disposed under a main pixel electrode for green adjacent to the auxiliary display area ADA from among the main pixel electrodes 310 located in the main display area MDA. That is, the first auxiliary pixel electrode 311g for green, the second auxiliary pixel electrode 312g for green, and the main pixel electrode for green may be electrically connected to the same pixel circuit. Accordingly, a pixel including the first auxiliary pixel electrode 311g for green and a pixel including the second auxiliary pixel electrode 312g for green may emit light in the same manner as a pixel including the main pixel electrode for green. That is, the pixel including the first auxiliary pixel electrode 311g for green and the pixel including the second auxiliary pixel electrode 312g for green may be copy pixels of the pixel including the main pixel electrode for green.

Likewise, the extension line 1915 electrically connected to the first auxiliary pixel electrode 311b for blue and the second auxiliary pixel electrode 312b for blue may be electrically connected to a pixel circuit disposed under a main pixel electrode for blue adjacent to the auxiliary display area ADA from among the main pixel electrodes 310 located in the main display area MDA. That is, the first auxiliary pixel electrode 311b for blue, the second auxiliary pixel electrode 312b for blue, and the main pixel electrode for blue may be electrically connected to the same pixel circuit. Accordingly, a pixel including the first auxiliary pixel electrode 311b for blue and a pixel including the second auxiliary pixel electrode 312b for blue may emit light in the same manner as a pixel including the main pixel electrode for blue. That is, the pixel including the first auxiliary pixel electrode 311b for blue and the pixel including the second auxiliary pixel electrode 312b for blue may be copy pixels of the pixel including the main pixel electrode for blue.

The extension lines 1911, 1913, and 1915 may include a transparent or translucent conductive material. For example, the extension lines 1911, 1913, and 1915 may include indium tin oxide (ITO), indium zinc oxide (IZO), zinc oxide (ZnO or ZnO₂), indium oxide (In₂O₃), indium gallium oxide (IGO), or aluminum zinc oxide (AZO).

At least a portion of the scan driver SD described above with reference to FIG. 1 may overlap the auxiliary display area ADA when viewed in a direction (the z-axis direction) perpendicular to the substrate 100 (i.e., in a plan view).

The scan driver SD may include a thin-film transistor and/or a capacitor, and the pixel circuit located in the main display area MDA may also include a thin-film transistor and/or a capacitor. Therefore, during a manufacturing process, the thin-film transistor and/or capacitor included in the scan driver SD may be directly formed on the same layer as, of the same material as, and simultaneously with the thin-film transistor and/or capacitor included in the pixel circuit located in the main display area MDA when the thin-film transistor and/or capacitor included in the pixel circuit are formed.

As described above, unlike the main display area MDA, there is no pixel circuit in the auxiliary display area ADA, and thus, at least a portion of the scan driver SD may be located in the auxiliary display area ADA. Accordingly, the overall display area of the display apparatus may be increased by using the main display area MDA and the auxiliary display area ADA, while the area of the peripheral area PA for the scan driver SD to be located may be relatively reduced. In another embodiment, a portion of the scan driver SD may be disposed under the connection line 315. In this case, the connection line 315 may function as a shield layer that protects the scan driver SD from external static electricity or the like.

Components shown in FIG. 2 but not explained, such as a buffer layer 111, a first gate insulating layer 113, a second gate insulating layer 115, and a first interlayer-insulating layer 117, are described below.

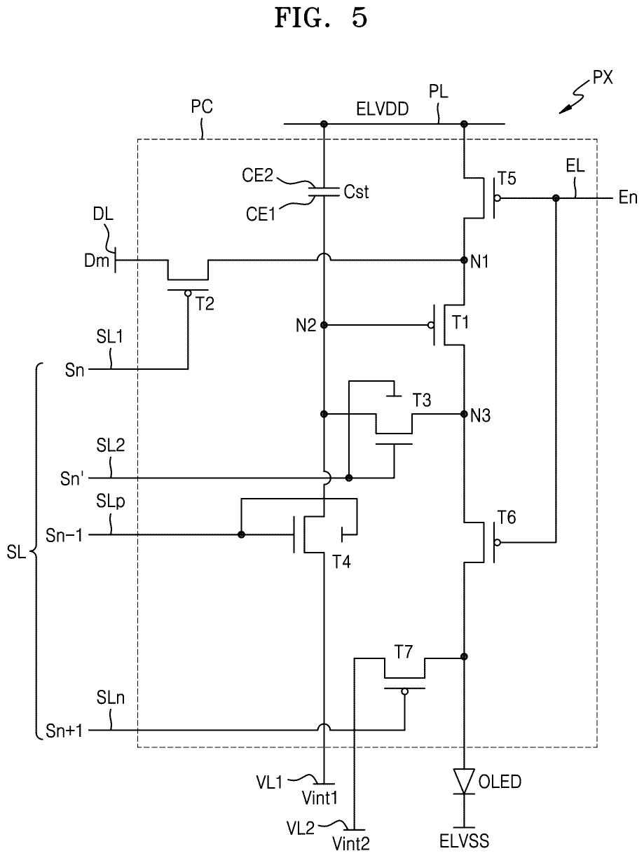

FIG. 5 is an equivalent circuit diagram of a pixel PX arranged in the main display area MDA of the display apparatus of FIG. 1. As shown in FIG. 5, the pixel PX arranged in the main display area MDA may include a pixel circuit PC and an organic light-emitting diode OLED including a main pixel electrode 310 (see FIG. 14) electrically connected to the pixel circuit PC.

The pixel circuit PC may include a plurality of thin-film transistors T1 to T7 and a storage capacitor Cst, as shown in FIG. 5. The plurality of thin-film transistors T1 to T7 and the storage capacitor Cst may be connected to signal lines SL1, SL2, SLp, SLn, EL, and DL, a first initialization voltage line VL1, a second initialization voltage line VL2, and a driving voltage line PL. At least any one of these lines, for example, the driving voltage line PL, may be shared by neighboring pixels PX.

The plurality of thin-film transistors T1 to T7 may include a driving transistor T1, a switching transistor T2, a compensation transistor T3, a first initialization transistor T4, an operation control transistor T5, an emission control transistor T6, and a second initialization transistor T7.

The organic light-emitting diode OLED may include the main pixel electrode 310 and a common electrode 330, where the main pixel electrode 310 may be connected to the driving transistor T1 via the emission control transistor T6 and receive a driving current, and the common electrode 330 may receive a second power voltage ELVSS. The organic light-emitting diode OLED may generate light of a luminance corresponding to the driving current.

Some of the plurality of thin-film transistors T1 to T7 may be n-channel metal-oxide-semiconductor field-effect-transistors (n-channel MOSFETs; NMOS), and the other ones may be p-channel MOSFETs (PMOS). For example, the compensation transistor T3 and the first initialization transistor T4 from among the plurality of thin-film transistors T1 to T7 may be NMOS, and the other ones may be PMOS. In some embodiments, the compensation transistor T3, the first initialization transistor T4, and the second initialization transistor T7 from among the plurality of thin-film transistors T1 to T7 may be NMOS, and the other ones may be PMOS. In some embodiments, the plurality of thin-film transistors T1 to T7 may all be NMOS or all be PMOS. Each of the plurality of thin-film transistors T1 to T7 may include amorphous silicon or polysilicon. In another embodiment, a thin-film transistor as an NMOS may include an oxide semiconductor. Hereinafter, it is described that the compensation transistor T3 and the first initialization transistor T4 are NMOS including an oxide semiconductor and the other ones are PMOS, for convenience of explanation.

The signal lines may include a first scan line SL1 configured to transmit a first scan signal Sn to the switching transistor T2, a second scan line SL2 configured to transmit a second scan signal Sn′ to the compensation transistor T3, a previous scan line SLp configured to transmit a previous scan signal Sn−1 to the first initialization transistor T4, a next scan line SLn configured to transmit a next scan signal Sn+1 to the second initialization transistor T7, an emission control line EL configured to transmit an emission control signal En to the operation control transistor T5 and the emission control transistor T6, and a data line DL which crosses the first scan line SL1 and is configured to transmit a data signal Dm to the switching transistor T2.

The driving voltage line PL may be configured to transmit the driving voltage ELVDD to the driving transistor T1, the first initialization voltage line VL1 may be configured to transmit a first initialization voltage Vint1 to the first initialization transistor T4 for initializing the driving transistor T1, and the second initialization voltage line VL2 may be configured to transmit a second initialization voltage Vint2 to the second initialization transistor T7 for initializing the main pixel electrode 310 of the organic light-emitting diode OLED.

A driving gate electrode of the driving transistor T1 may be connected to the storage capacitor Cst via a second node N2, where any one of a source region and a drain region of the driving transistor T1 may be connected to the driving voltage line PL via the operation control transistor T5 and a first node N1, and the other one of the source region and the drain region of the driving transistor T1 may be electrically connected to the main pixel electrode 310 of the organic light-emitting diode OLED via the emission control transistor T6 and a third node N3. The driving transistor T1 may receive the data signal Dm according to a switching operation of the switching transistor T2 and supply a driving current to the organic light-emitting diode OLED. In other words, the driving transistor T1 may control an amount of current that flows to the organic light-emitting diode OLED from the first node N1 electrically connected to the driving voltage line PL, in response to a voltage applied to the second node N2 that varies according to the data signal Dm.

A switching gate electrode of the switching transistor T2 may be connected to the first scan line SL1 configured to transmit the first scan signal Sn to the switching transistor T2, where any one of a source region and a drain region of the switching transistor T2 may be connected to the data line DL, and the other one of the source region and the drain region of the switching transistor T2 may be connected to the driving voltage line PL via the operation control transistor T5 and to the driving transistor T1 via the first node N1. In response to a voltage applied to the first scan line SL1, the switching transistor T2 may be configured to transmit the data signal Dm from the data line DL to the first node N1. In other words, the switching transistor T2 may be turned on in response to the first scan signal Sn via the first scan line SL1 and perform a switching operation for transmitting the data signal Dm received via the data line DL to the driving transistor T1 via the first node N1.

A compensation gate electrode of the compensation transistor T3 may be connected to the second scan line SL2. Any one of a source region and a drain region of the compensation transistor T3 may be connected to the main pixel electrode 310 of the organic light-emitting diode OLED via the emission control transistor T6 and the third node N3. The other one of the source region and the drain region of the compensation transistor T3 may be connected to a first capacitor electrode CE1 of the storage capacitor Cst and the driving gate electrode of the driving transistor T1 via the second node N2. The compensation transistor T3 as described above may be turned on in response to the second scan signal Sn′ received via the second scan line SL2 and diode-connect the driving transistor T1.

A first initialization gate electrode of the first initialization transistor T4 may be connected to the previous scan line SLp. Any one of a source region and a drain region of the first initialization transistor T4 may be connected to the first initialization voltage line VL1. The other one of the source region and the drain region of the first initialization transistor T4 may be connected to the first capacitor electrode CE1 of the storage capacitor Cst and the driving gate electrode of the driving transistor T1 via the second node N2. The first initialization transistor T4 may be configured to apply the first initialization voltage Vint1 to the second node N2 from the first initialization voltage line VL1, in response to a voltage applied to the previous scan line SLp. In other words, the first initialization transistor T4 may be turned on in response to the previous scan signal Sn−1 received via the previous scan line SLp and perform an initialization operation for applying the first initialization voltage Vint1 to the driving gate electrode of the driving transistor T1 and initializing a voltage of the driving gate electrode of the driving transistor T1.

An operation control gate electrode of the operation control transistor T5 may be connected to the emission control line EL, where any one of a source region and a drain region of the operation control transistor T5 may be connected to the driving voltage line PL, and the other one may be connected to the driving transistor T1 and the switching transistor T2 via the first node N1.

An emission control gate electrode of the emission control transistor T6 may be connected to the emission control line EL, where any one of a source region and a drain region of the emission control transistor T6 may be connected to the driving transistor T1 and the compensation transistor T3 via the third node N3, and the other one of the source region and the drain region of the emission control transistor T6 may be electrically connected to the main pixel electrode 310 of the organic light-emitting diode OLED.

The operation control transistor T5 and the emission control transistor T6 may be simultaneously turned on in response to the emission control signal En received via the emission control line EL, so that the driving voltage ELVDD is applied to the organic light-emitting diode OLED and a driving current flows in the organic light-emitting diode OLED. A second initialization gate electrode of the second initialization transistor T7 may be connected to the next scan line SLn, where any one of a source region and a drain region of the second initialization transistor T7 may be connected to the main pixel electrode 310 of the organic light-emitting diode OLED, and the other one of the source region and the drain region of the second initialization transistor T7 may be connected to the second initialization transistor T7 and receive the second initialization voltage Vint2. The second initialization transistor T7 may be turned on in response to the next scan signal Sn+1 received via the next scan line SLn, so that the main pixel electrode 310 of the organic light-emitting diode OLED is initialized. The next scan line SLn and the first scan line SL1 may be the same line. In this case, the corresponding scan line may be configured to transmit the same electrical signal with a time difference and may function as the first scan line SL1 and also as the next scan line SLn. In other words, the next scan line SLn may include a first scan line of a pixel, which is adjacent to the pixel PX shown in FIG. 5, and electrically connected to the data line DL.

The second initialization transistor T7 may be connected to the next scan line SLn, as shown in FIG. 5. However, the present disclosure is not limited thereto, and the second initialization transistor T7 may be connected to the emission control line EL and driven according to the emission control signal En in another embodiment.

The storage capacitor Cst may include the first capacitor electrode CE1 and a second capacitor electrode CE2. The first capacitor electrode CE1 of the storage capacitor Cst may be connected to the driving gate electrode of the driving transistor T1 via the second node N2, and the second capacitor electrode CE2 of the storage capacitor Cst may be connected to the driving voltage line PL. The storage capacitor Cst may store a charge corresponding to a voltage difference between the driving gate electrode voltage of the driving transistor T1 and the driving voltage ELVDD.

A detailed operation of each pixel PX according to an embodiment is described below. During an initialization period, when the previous scan signal Sn−1 is transmitted via the previous scan line SLp to the first initialization transistor T4, the first initialization transistor T4 may be turned on in response to the previous scan signal Sn−1, and the driving transistor T1 may be initialized according to the first initialization voltage Vint1 applied via the first initialization voltage line VL1.

During a data programming period, when the first scan signal Sn and the second scan signal Sn′ are transmitted via the first scan line SL1 and the second scan line SL2, respectively, the switching transistor T2 and the compensation transistor T3 may be turned on in response to the first scan signal Sn and the second scan line Sn′. In this case, the driving transistor T1 may be diode-connected by the compensation transistor T3 that is turned on, and biased in a forward direction. Then, a compensation voltage (Dm+Vth, where Vth has a negative value), which is obtained by subtracting the data signal Dm received via the data line DL by a threshold voltage Vth of the driving transistor T1, may be applied to the driving gate electrode G1 of the driving transistor T1. The driving voltage ELVDD and the compensation voltage (Dm+Vth) are applied to opposite ends of the storage capacitor Cst, respectively, and a charge corresponding to a voltage difference between the opposite ends of the storage capacitor Cst may be stored in the storage capacitor Cst.

During an emission period, the operation control transistor T5 and the emission control transistor T6 may be turned on in response to the emission control signal En received via the emission control line EL. A driving current corresponding to a voltage difference between the voltage of the driving gate electrode G1 of the driving transistor T1 and the driving voltage ELVDD may be generated, and the driving current may be supplied to the organic light-emitting diode OLED via the emission control transistor T6.

As described above, some of the plurality of thin-film transistors T1 to T7 may include an oxide semiconductor. For example, the compensation transistor T3 and the first initialization transistor T4 may include an oxide semiconductor.

In a case of polysilicon, which is highly reliable, it may be precisely controlled so that an intended current flows. Accordingly, when a semiconductor layer including highly-reliable polysilicon is included in the driving transistor T1 that directly affects a brightness of the display apparatus, a high-resolution display apparatus may be implemented. In addition, an oxide semiconductor has high carrier mobility and low leakage current, and thus, a voltage drop is not large even when a driving time is long. In other words, in an oxide semiconductor, a change in color of an image according to a voltage drop is not large even when the display apparatus is driven at low frequencies, and thus, the display apparatus may be driven at low frequencies. Accordingly, when the compensation transistor T3 and the first initialization transistor T4 include an oxide semiconductor, a display apparatus with reduced power consumption while preventing leakage current may be implemented.

Meanwhile, such an oxide semiconductor may be sensitive to light, and thus, an amount of current or the like may vary depending on external light. Accordingly, a metal layer may be disposed under the oxide semiconductor and absorb or reflect the external light. Accordingly, as shown in FIG. 5, in each of the compensation transistor T3 and the first initialization transistor T4 including the oxide semiconductor, a gate electrode may be over and under an oxide semiconductor layer. In other words, when viewed in the direction (the z-axis direction) perpendicular to the upper surface of the substrate 100 (i.e., in a plan view), the metal layer disposed under the oxide semiconductor may overlap the oxide semiconductor.

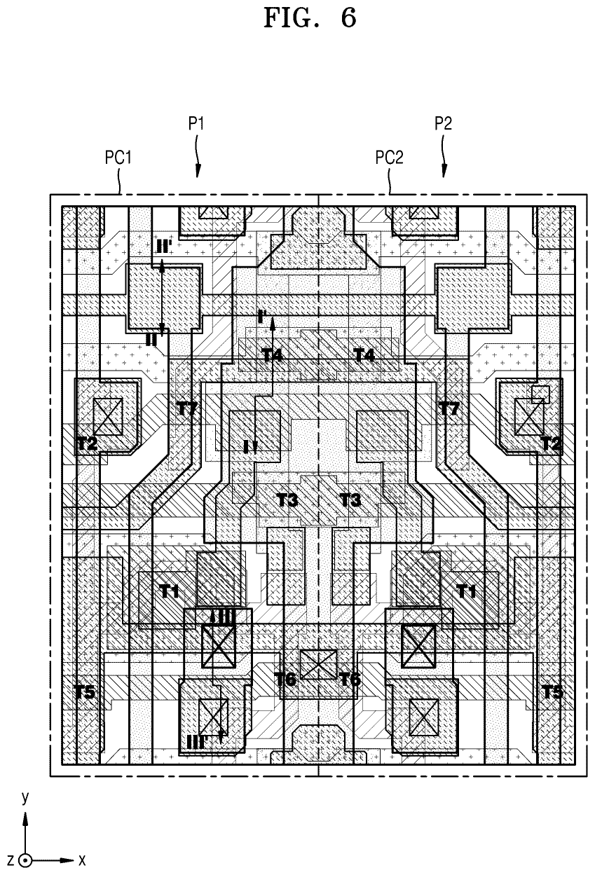

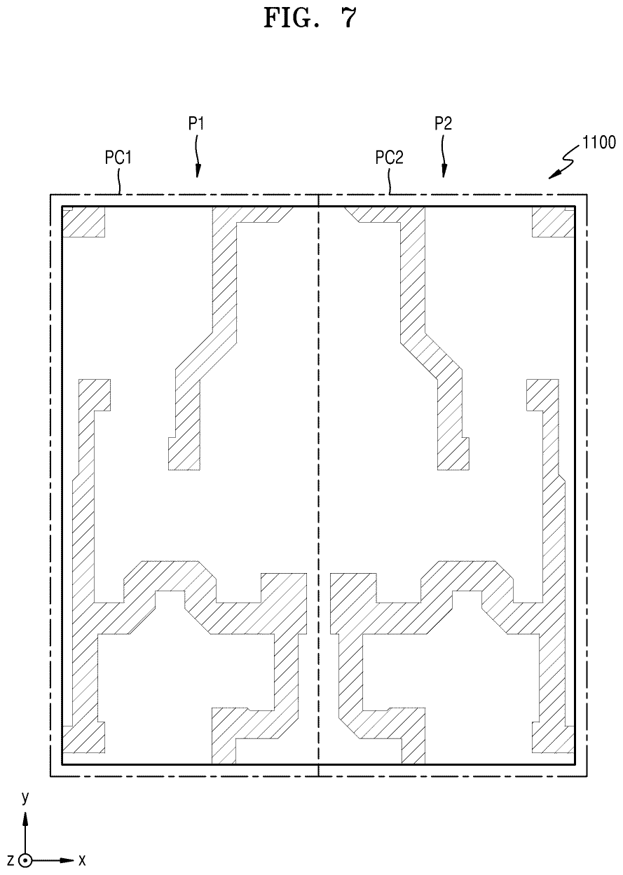

FIG. 6 is a schematic layout diagram illustrating positions of transistors, a capacitor, and the like in pixels arranged in the main display area MDA of the display apparatus of FIG. 1, FIGS. 7 to 13 are schematic layout diagrams illustrating components of the display apparatus shown in FIG. 6, such as the transistors and the capacitor, for each layer, and FIG. 14 is a schematic cross-sectional view illustrating cross-sections of the display apparatus, taken along lines I-I′, II-II′, and III-III′ in FIG. 6.

As shown in these drawings, the display apparatus may include a first pixel P1 and a second pixel P2 that are located in the main display area MDA and adjacent to each other. The first pixel P1 and the second pixel P2 may be symmetrical to each other with respect to a virtual line, as shown in FIG. 6, etc. However, unlike this, the first pixel P1 and the second pixel P2 may have the same structure rather than a symmetrical structure. The first pixel P1 may include a first pixel circuit PC1, and the second pixel P2 may include a second pixel circuit PC2. Hereinafter, for convenience of explanation, some conductive patterns are described based on the first pixel circuit PC1, but these conductive patterns may also be symmetrically arranged in the second pixel circuit PC2. An organic light-emitting element, that is, the organic light-emitting diode OLED, may be electrically connected to each of the first pixel circuit PC1 and the second pixel circuit PC2.

A buffer layer 111 (see FIG. 14) may be disposed on the substrate 100, where the buffer layer 111 includes silicon oxide, silicon nitride, or silicon oxynitride. The buffer layer 111 may prevent a phenomenon in which metal atoms or impurities from the substrate 100 diffuse to a first semiconductor layer 1100 disposed over the substrate 100. In addition, during a crystallization process of forming the first semiconductor layer 1100, the buffer layer 111 may adjust a rate at which heat is provided, so that the first semiconductor layer 1100 is uniformly crystallized.

The first semiconductor layer 1100, as shown in FIG. 7, may be disposed on the buffer layer 111. The first semiconductor layer 1100 may include a silicon semiconductor. For example, the first semiconductor layer 1100 may include amorphous silicon or polysilicon. For example, the first semiconductor layer 1100 may include polysilicon crystallized at a low temperature. In another embodiment, ions may be injected into at least a portion of the first semiconductor layer 1100.

Because the driving transistor T1, the switching transistor T2, the operation control transistor T5, the emission control transistor T6, and the second initialization transistor T7 may be PMOS, as described above, in this case, these thin-film transistors may be located along the first semiconductor layer 1100, as shown in FIG. 7.

A first gate insulating layer 113 (see FIG. 14) may be disposed over the substrate 100 and cover the first semiconductor layer 1100. The first gate insulating layer 113 may include an insulating material. For example, the first gate insulating layer 113 may include silicon oxide, silicon nitride, silicon oxynitride, aluminum oxide, or the like.

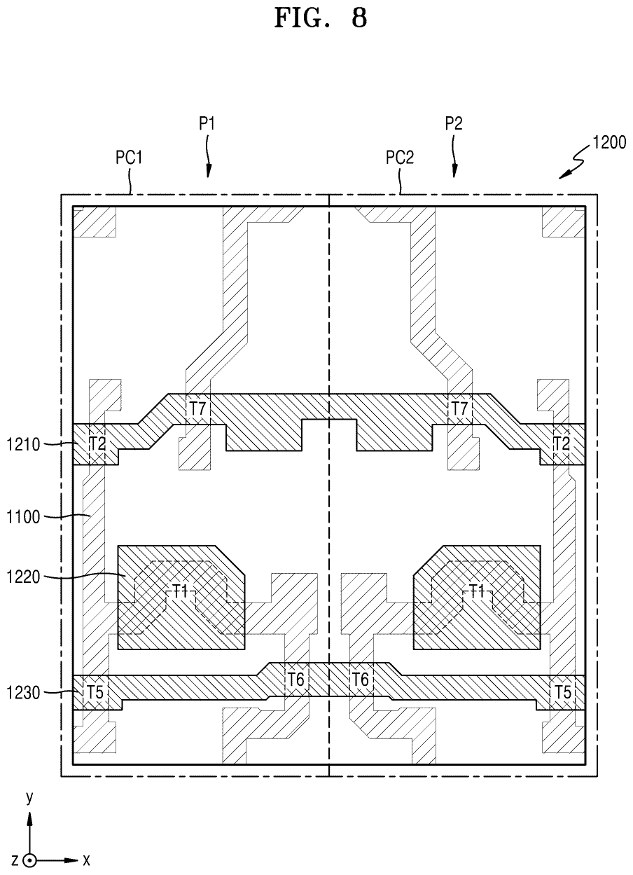

A first gate layer 1200, as shown in FIG. 8, may be disposed on the first gate insulating layer 113. In FIG. 8, the first semiconductor layer 1100 is shown together with the first gate layer 1200, for convenience of description. The first gate layer 1200 may include a first gate line 1210, a first gate electrode 1220, and a second gate line 1230.

The first gate line 1210 may extend in the second direction (the x-axis direction). The first gate line 1210 may correspond to the scan line SL in FIG. 1 and the first scan line SL1 or the next scan line SLn in FIG. 5. In other words, in the first pixel P1 shown in FIG. 8, the first gate line 1210 may correspond to the first scan line SL1 in FIG. 5, and in a pixel adjacent to the first pixel P1 in the +y direction, the first gate line 1210 may correspond to the next scan line SLn in FIG. 5. Accordingly, the first scan signal Sn and the next scan signal Sn+1 may be applied to the pixels via the first gate line 1210. Portions of the first gate line 1210 overlapping the first semiconductor layer 1100 in a plan view may include the switching gate electrode of the switching transistor T2 and the second initialization gate electrode of the second initialization transistor T7.

The first gate electrode 1220 may have an isolated shape. The first gate electrode 1220 may include the driving gate electrode of the driving transistor T1. For reference, a portion of the first semiconductor layer 1100 overlapping the first gate electrode 1220 and a portion therearound may be referred to as a driving semiconductor layer.

The second gate line 1230 may extend in the second direction (the x-axis direction). The second gate line 1230 may correspond to the emission control line EL in FIG. 5. Portions of the second gate line 1230 overlapping the first semiconductor layer 1100 in a plan view may include the operation control gate electrode of the operation control transistor T5 and the emission control gate electrode of the emission control transistor T6. The emission control signal En may be applied to the pixels via the second gate line 1230.

The first gate layer 1200 may include a metal, an alloy, a conductive metal oxide, a transparent conductive material, or the like. For example, the first gate layer 1200 may include silver (Ag), an Ag-containing alloy, molybdenum (Mo), a Mo-containing alloy, aluminum (Al), an Al-containing alloy, aluminum nitride (AlN), tungsten (W), tungsten nitride (WN), copper (Cu), nickel (Ni), chrome (Cr), chrome nitride (CrN), titanium (Ti), tantalum (Ta), platinum (Pt), scandium (Sc), indium tin oxide (ITO), indium zinc oxide (IZO), or the like. The first gate layer 1200 may have a multi-layer structure, such as a two-layer structure of a Mo layer and an Al layer, or a three-layer structure of a Mo layer, an Al layer, and another Mo layer.

A second gate insulating layer 115 (see FIG. 14) may be disposed on the first gate insulating layer 113 and cover the first gate layer 1200. The second gate insulating layer 115 may include the same/similar insulating material as/to the first gate insulating layer 113.

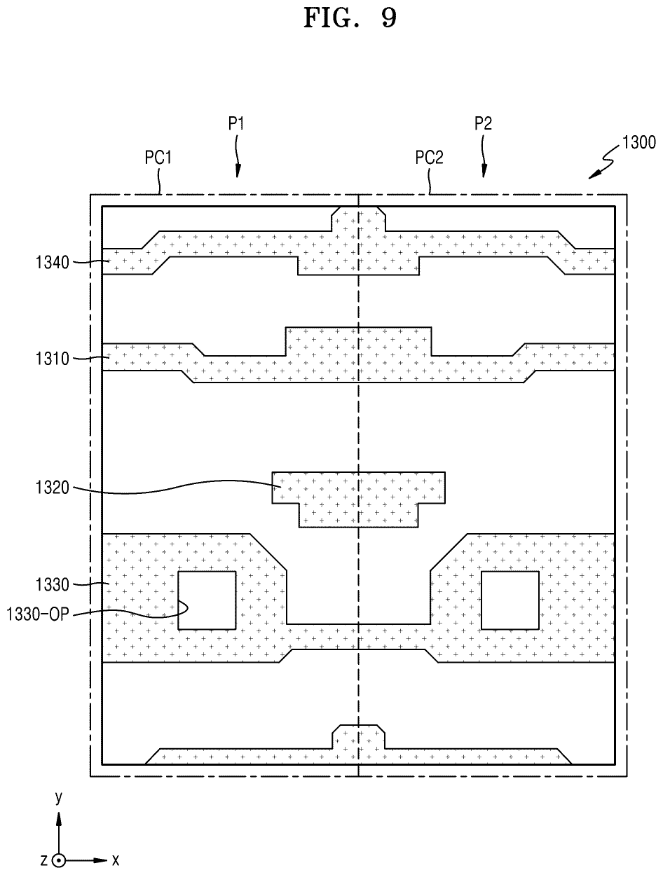

A second gate layer 1300, as shown in FIG. 9, may be disposed on the second gate insulating layer 115. The second gate layer 1300 may include a third gate line 1310, a fourth gate line 1320, a capacitor upper electrode 1330, and a first initialization voltage line 1340 (i.e., the first initialization voltage line VL1 in FIG. 5).

The third gate line 1310 may extend in the second direction (the x-axis direction). The third gate line 1310 may correspond to the previous scan line SLp in FIG. 5. When viewed in the direction (the z-axis direction) perpendicular to the substrate 100 (i.e., in a plan view), the third gate line 1310 may be apart from the first gate line 1210. The previous scan signal Sn−1 may be applied to the pixels via the third gate line 1310. A portion of the third gate line 1310 overlapping a second semiconductor layer 1400 to be described below in a plan view may include a first initialization lower gate electrode of the first initialization transistor T4.

The fourth gate line 1320 may also extend in the second direction (the x-axis direction) and may have an isolated shape. The fourth gate line 1320 may be electrically connected to a sixth gate line 1530 described below and correspond to the second scan line SL2 in FIG. 5. When viewed in the direction (the z-axis direction) perpendicular to the substrate 100 (i.e., in a plan view), the fourth gate line 1320 may be apart from the first gate line 1210 and the third gate line 1310. The second scan signal Sn′ may be applied to the pixels through the fourth gate line 1320. A portion of the fourth gate line 1320 overlapping the second semiconductor layer 1400 to be described below in a plan view may include a compensation lower gate electrode of the compensation transistor T3.

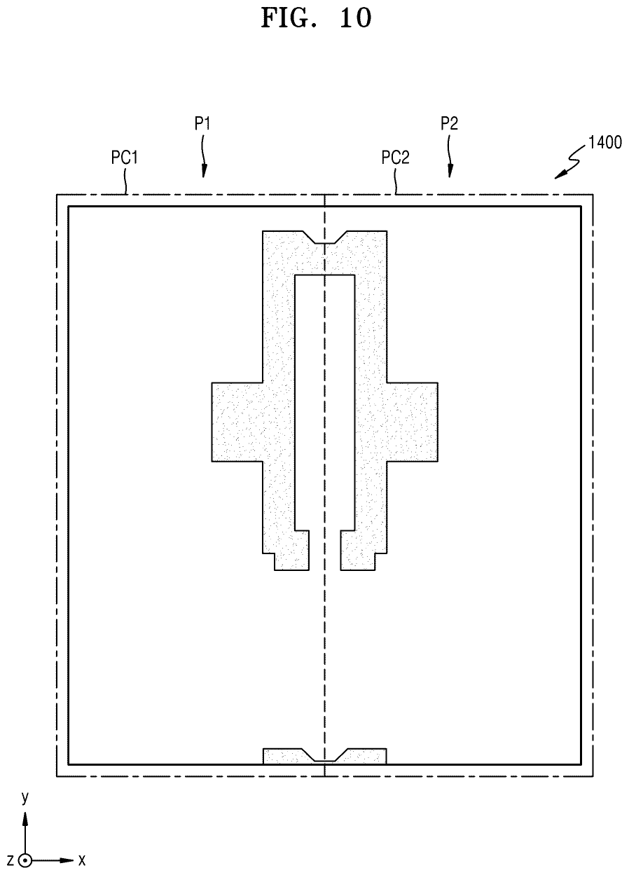

The third gate line 1310 and the fourth gate line 1320 may be disposed under the second semiconductor layer 1400 to be described below with reference to FIG. 10 and may function as gate electrodes and also as lower protective metals for protecting portions of the second semiconductor layer 1400 overlapping the third gate line 1310 and the fourth gate line 1320 in a plan view.

The capacitor upper electrode 1330 may overlap the first gate electrode 1220 in a plan view and extend in the second direction (the x-axis direction). The capacitor upper electrode 1330 described above may constitute the storage capacitor Cst together with the first gate electrode 1220, to correspond to the second capacitor electrode CE2 in FIG. 5. The driving voltage ELVDD may be applied to the capacitor upper electrode 1330. In addition, a hole passing through the capacitor upper electrode 1330 may be defined in the capacitor upper electrode 1330, and at least a portion of the first gate electrode 1220 may overlap the hole in a plan view.

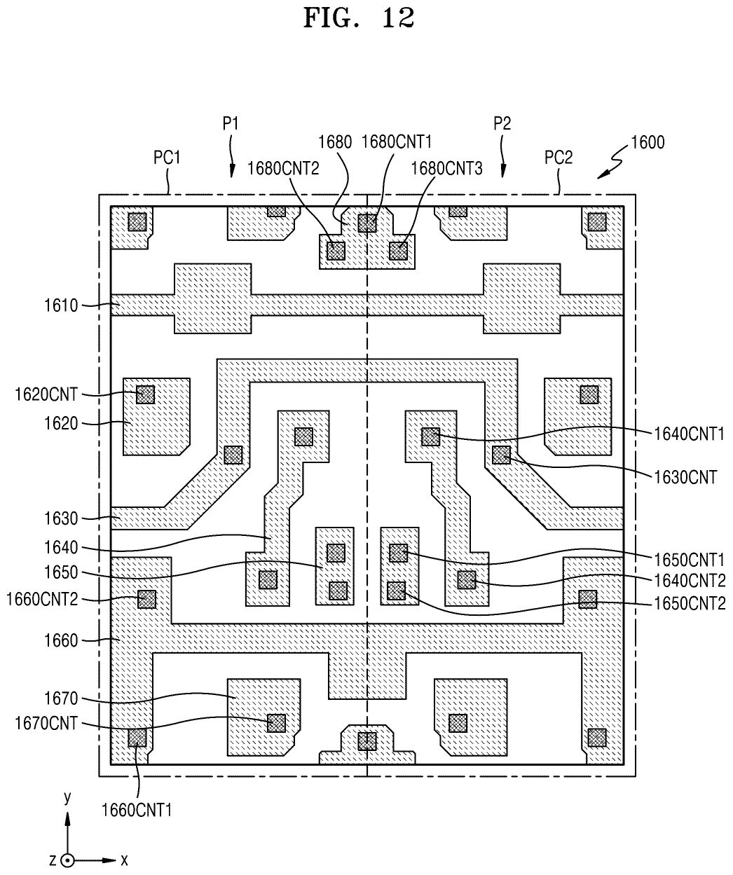

The first initialization voltage line 1340 corresponding to the first initialization voltage line VL1 in FIG. 5 may extend in the second direction (the x-axis direction). When viewed in the direction (the z-axis direction) perpendicular to the substrate 100 (i.e., in a plan view), the first initialization voltage line 1340 may be apart from the third gate line 1310. The first initialization voltage Vint1 may be applied to the pixels through the first initialization voltage line 1340. The first initialization voltage line 1340 may at least partially overlap the second semiconductor layer 1400 to be described below in a plan view and may be configured to apply the first initialization voltage line 1340 to the second semiconductor layer 1400. The first initialization voltage line 1340 may be electrically connected to the second semiconductor layer 1400 through contact holes 1680CNT1, 1680CNT2, and 1680CNT3 to be described below with reference to FIG. 12.

The second gate layer 1300 may include a metal, an alloy, a conductive metal oxide, a transparent conductive material, or the like. For example, the second gate layer 1300 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The second gate layer 1300 may have a multi-layer structure, such as a two-layer structure of a Mo layer and an Al layer, or a three-layer structure of a Mo layer, an Al layer, and another Mo layer.

A first interlayer-insulating layer 117 (see FIG. 14) may be disposed on the second gate insulating layer 115 and cover the second gate layer 1300. The first interlayer-insulating layer 117 may include an insulating material. For example, the first interlayer-insulating layer 117 may include silicon oxide, silicon nitride, silicon oxynitride, aluminum oxide, or the like.

The second semiconductor layer 1400 shown in FIG. 10 may be disposed on the first interlayer-insulating layer 117. As described above, the second semiconductor layer 1400 may include an oxide semiconductor. The second semiconductor layer 1400 may be disposed on a layer different from a layer on which the first semiconductor layer 1100 is disposed, and may not overlap the first semiconductor layer 1100 when viewed in the direction (the z-axis direction) perpendicular to the substrate 100 (i.e., in a plan view).

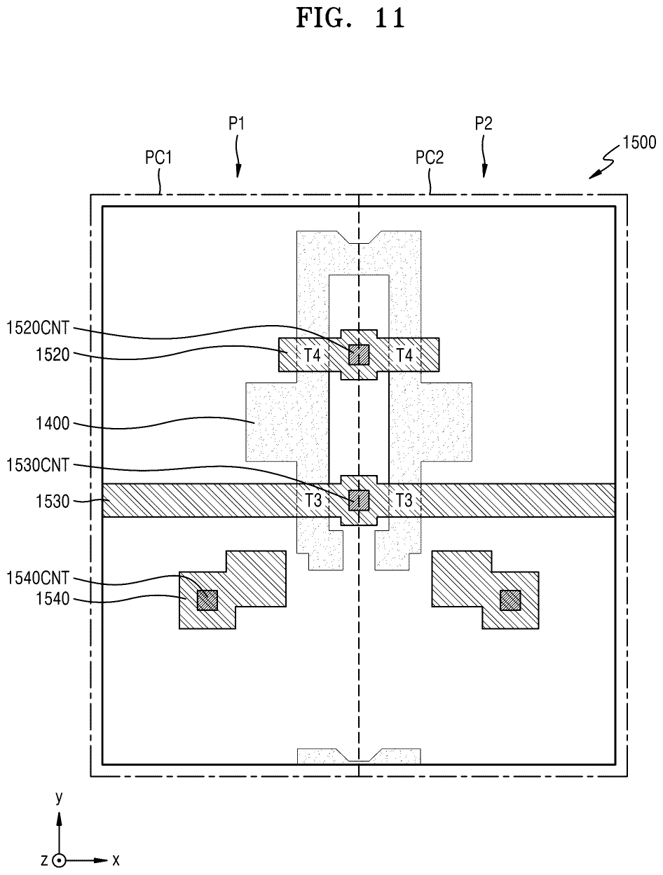

The third gate insulating layer 118 may be disposed on the first interlayer-insulating layer 117 and cover the second semiconductor layer 1400. The third gate insulating layer 118 may include an insulating material. However, as shown in FIG. 14, the third gate insulating layer 118 may be disposed only on a portion of the second semiconductor layer 1400 and not on the first interlayer-insulating layer 117. In the latter case, the third gate insulating layer 118 may have the same pattern as a third gate layer 1500 to be described below with reference to FIG. 11. In other words, when viewed in the direction (the z-axis direction) perpendicular to the substrate 100 (i.e., in a plan view), the third gate insulating layer 118 may completely or almost completely overlap the third gate layer 1500. This is because the third gate insulating layer 118 and the third gate layer 1500 are simultaneously patterned. Accordingly, in the second semiconductor layer 1400, source regions and drain regions may not be covered with the third gate insulating layer 118 except for channel regions overlapping the third gate layer 1500 in a plan view. The source regions and drain regions may be in direct contact with the second interlayer-insulating layer 119, as shown in FIG. 14. The third gate insulating layer 118 may include silicon oxide, silicon nitride, silicon oxynitride, aluminum oxide, or the like.

The third gate layer 1500 shown in FIG. 11 may be disposed on the third gate insulating layer 118. The third gate layer 1500 may include a fifth gate line 1520, a sixth gate line 1530, and a first transmission line 1540.

The fifth gate line 1520 may extend in the second direction (the x-axis direction) and may have an isolated shape. When viewed in the direction (the z-axis direction) perpendicular to the substrate 100 (i.e., in a plan view), the fifth gate line 1520 may overlap the third gate line 1310. A portion of the fifth gate line 1520 overlapping the second semiconductor layer 1400 in a plan view may include a first initialization upper gate electrode of the first initialization transistor T4. A portion of the second semiconductor layer 1400 overlapping the fifth gate line 1520 and a portion therearound in a plan view may be referred to as a first initialization semiconductor layer. The fifth gate line 1520 may be electrically connected to the third gate line 1310. For example, the fifth gate line 1520 may be electrically connected to the third gate line 1310 through a contact hole 1520CNT defined in an insulating layer between the fifth gate line 1520 and the third gate line 1310. Accordingly, the fifth gate line 1520 may correspond to the previous scan line SLp in FIG. 5 together with the third gate line 1310. Accordingly, the previous scan signal Sn−1 may be applied to pixels through the fifth gate line 1520 and/or the third gate line 1310.

The sixth gate line 1530 may extend in the second direction (the x-axis direction). When viewed in the direction (the z-axis direction) perpendicular to the substrate 100 (i.e., in a plan view), the sixth gate line 1530 may overlap the fourth gate line 1320. A portion of the sixth gate line 1530 overlapping the second semiconductor layer 1400 in a plan view may include a compensation upper gate electrode of the compensation transistor T3. The sixth gate line 1530 may be electrically connected to the fourth gate line 1320. For example, the sixth gate line 1530 may be electrically connected to the fourth gate line 1320 through a contact hole 1530CNT defined in an insulating layer between the sixth gate line 1530 and the fourth gate line 1320. Accordingly, the sixth gate line 1530 may correspond to the second scan line SL2 in FIG. 5 together with the fourth gate line 1320. Accordingly, the second scan signal Sn′ may be applied to pixels through the sixth gate line 1530 and/or the fourth gate line 1320.

The first transmission line 1540 may be electrically connected to the first gate electrode 1220, which is a driving gate electrode, through the contact hole 1540CNT passing through an opening 1330-OP of the capacitor upper electrode 1330. The first transmission line 1540 may be configured to transmit, to the first gate electrode 1220, the first initialization voltage Vint1 transmitted through the first initialization transistor T4.

The third gate layer 1500 may include a metal, an alloy, a conductive metal oxide, a transparent conductive material, or the like. For example, the third gate layer 1500 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The third gate layer 1500 may have a multi-layer structure, such as a two-layer structure of a Mo layer and an Al layer, or a three-layer structure of a Mo layer, an Al layer, and another Mo layer.

The second interlayer-insulating layer 119 (see FIG. 14) may cover at least a portion of the third gate layer 1500 in FIG. 11. The second interlayer-insulating layer 119 may include an insulating material. For example, the second interlayer-insulating layer 119 may include silicon oxide, silicon nitride, silicon oxynitride, aluminum oxide, or the like. For reference, in FIG. 14, the upper surface of the second interlayer-insulating layer 119 is shown to be approximately flat. However, unlike this, the upper surface of the second interlayer-insulating layer 119 may not be flat but correspond to the shapes of components disposed under the second interlayer-insulating layer 119.

A first connection electrode layer 1600 shown in FIG. 12 may be disposed on the second interlayer-insulating layer 119. The first connection electrode layer 1600 may include a horizontal connection line 1610, a second transmission line 1620, a second initialization voltage line 1630, a third transmission line 1640, a fourth transmission line 1650, a fifth transmission line 1660, a sixth transmission line 1670, and a seventh transmission line 1680.

The horizontal connection line 1610 may extend in the second direction (the x-axis direction). The horizontal connection line 1610 described above with reference to FIGS. 2 to 4 may be implemented through the horizontal connection line 1610 in FIG. 12. In a portion of the main display area MDA adjacent to the pad area PADA, that is, a portion near the first edge E1 or a portion near the second edge E2, the horizontal connection line 1610 may be used for other purposes. This is described below.

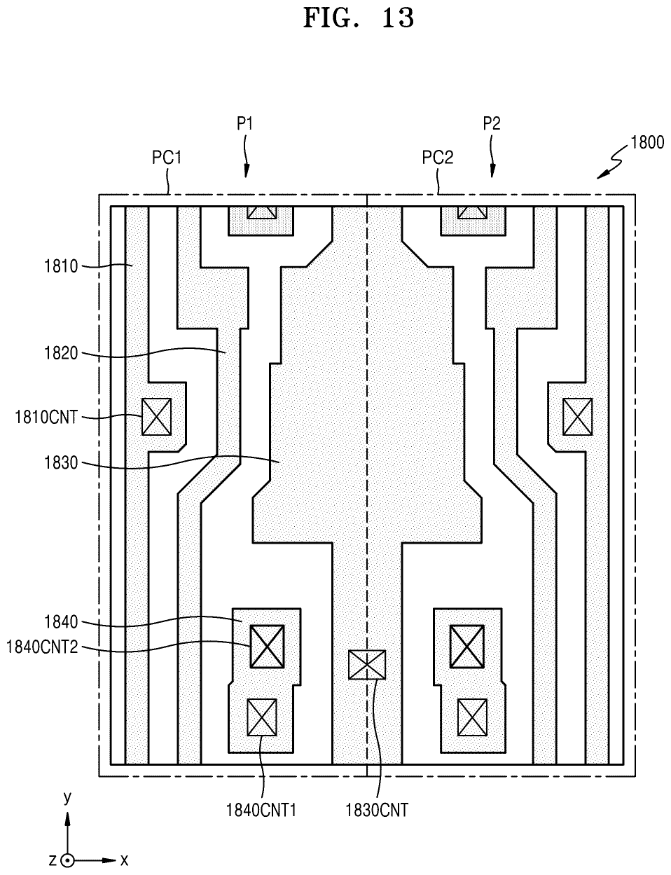

The second transmission line 1620 may be electrically connected to the first semiconductor layer 1100 through a contact hole 1620CNT. A data signal Dm from a data line 1810 to be described below with reference to FIG. 13 may be transmitted to the first semiconductor layer 1100 through the second transmission line 1620 and applied to the switching transistor T2.

The second initialization voltage line 1630 may extend in the second direction (the x-axis direction). The second initialization voltage line 1630, which corresponds to the second initialization voltage line VL2 in FIG. 2, may be configured to apply the second initialization voltage Vint2 to the pixels. The second initialization voltage line 1630 may be electrically connected to the first semiconductor layer 1100 through a contact hole 1630CNT, and thus, the second initialization voltage Vint2 may be transmitted to the first semiconductor layer 1100 and applied to the second initialization transistor T7.

The third transmission line 1640 may electrically connect the second semiconductor layer 1400 to the first transmission line 1540 through contact holes 1640CNT1 and 1640CNT2 defined at one side and the other side of the third transmission line 1640. Because the first transmission line 1540 is electrically connected to the first gate electrode 1220, which is a driving gate electrode, the third transmission line 1640 may electrically connect the first initialization semiconductor layer, which is a portion of the second semiconductor layer 1400, to the driving gate electrode. The first initialization voltage Vint1 may be transmitted to the first gate electrode 1220, which is a driving gate electrode, through the second semiconductor layer 1400, the third transmission line 1640, and the first transmission line 1540.

The fourth transmission line 1650 may electrically connect the second semiconductor layer 1400 to the first semiconductor layer 1100 through contact holes 1650CNT1 and 1650CNT2 defined at one side and the other side of the fourth transmission line 1650. In other words, the fourth transmission line 1650 may electrically connect the compensation transistor T3 and the driving transistor T1 to each other.

The fifth transmission line 1660 may extend in the second direction (the x-axis direction). The driving voltage ELVDD, which is a constant voltage from a driving voltage line 1830 to be described below with reference to FIG. 13, may be transmitted to the fifth transmission line 1660, and the fifth transmission line 1660 may be electrically connected to the first semiconductor layer 1100 through a contact hole 1660CNT1 and transmit the driving voltage ELVDD to the first semiconductor layer 1100, specifically, to the operation control transistor T5. In addition, the fifth transmission line 1660, which is electrically connected to the capacitor upper electrode 1330 (i.e., the second capacitor electrode CE2 in FIG. 5) through a contact hole 1660CNT2, may configured to transmit the driving voltage ELVDD to the capacitor upper electrode 1330.

The sixth transmission line 1670 may be electrically connected to the first semiconductor layer 1100 through a contact hole 1670CNT. The sixth transmission line 1670 may be configured to transmit the driving current or the second initialization voltage Vint2 from the first semiconductor layer 1100 to the organic light-emitting diode OLED.

The seventh transmission line 1680 may be electrically connected to the second semiconductor layer 1400 through contact holes 1680CNT2 and 1680CNT3. In addition, the seventh transmission line 1680 may be electrically connected to the first initialization voltage line 1340 in FIG. 9 through a contact hole 1680CNT1. Accordingly, the seventh transmission line 1680 may be configured to transmit the first initialization voltage Vint1 from the first initialization voltage line 1340 to the first initialization transistor T4.

The first connection electrode layer 1600 may include a metal, an alloy, a conductive metal oxide, a transparent conductive material, or the like. For example, the first connection electrode layer 1600 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The first connection electrode layer 1600 may have a multi-layer structure, such as a two-layer structure of a Ti layer and an Al layer, or a three-layer structure of a Ti layer, an Al layer, and another Ti layer.

A third interlayer-insulating layer 121 (see FIG. 14) may be disposed on the second interlayer-insulating layer 119 and cover the first connection electrode layer 1600. The third interlayer-insulating layer 121 may include an insulating material. For example, the third interlayer-insulating layer 121 may include silicon oxide, silicon nitride, silicon oxynitride, aluminum oxide, or the like. In another embodiment, the third interlayer-insulating layer 121 may include an organic insulating material. For example, the third interlayer-insulating layer 121 may include photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any blends thereof.

For reference, FIG. 14 shows an example in which the third interlayer-insulating layer 121 includes an organic insulating material and has a substantially flat upper surface. However, when the third interlayer-insulating layer 121 includes an inorganic insulating material, the upper surface of the third interlayer-insulating layer 121 may not be flat but correspond to the shapes of components disposed under the third interlayer-insulating layer 121, as shown in FIG. 2.

A second connection electrode layer 1800 shown in FIG. 13 may be disposed on the third interlayer-insulating layer 121. The second connection electrode layer 1800 may include a data line 1810, a vertical connection line 1820, a driving voltage line 1830, and a tenth transmission line 1840.

The data line 1810 may extend in a first direction (the y-axis direction). The data line 1810 may correspond to the data line DL in FIGS. 1 and 5. The data line 1810 may be electrically connected to the second transmission line 1620 through a contact hole 1810CNT, and a data signal Dm from the data line 1810 may be transmitted to the first semiconductor layer 1100 through the second transmission line 1620 and applied to the switching transistor T2.

The vertical connection line 1820 may extend substantially in the first direction (the y-axis direction). As described above, in a portion of the main display area MDA adjacent to the pad area PADA and adjacent to the first edge E1 or the second edge E2, the horizontal connection line 1610 may be used for other purposes without being electrically connected to the common voltage supply line 11. The vertical connection line 1820 may be used together with the horizontal connection line 1610 in such cases.

As described above, the driving chip 20 may generate a data signal, and the data signal may be transmitted to the pixels in the main display area MDA through the data line DL. To this end, the driving chip 20 and the data line DL may be electrically connected to each other. However, in a portion of the main display area MDA adjacent to the pad area PADA, a portion (hereinafter referred to as a ‘first corner portion’) near the first edge E1 or a portion (hereinafter referred to as a ‘second corner portion’) near the second edge E2 may not have enough area, and thus it may not be easy to connect the driving chip 20 to the data line DL due to insufficient space (i.e., insufficient area). In this case, in the first and second corner portions, the data line DL may not be directly connected to the driving chip 20, but may be electrically connected to the driving chip 20 through the horizontal connection line 1610 and the vertical connection line 1820.

For example, in the first corner portion, one data line DL or 1810 may be electrically connected to the horizontal connection line 1610 through a contact hole defined in the third interlayer-insulating layer 121, and, in a pixel located in the +x direction from the first corner portion, the horizontal connection line 1610 may be electrically connected to the vertical connection line 1820 through a contact hole defined in the third interlayer-insulating layer 121 and the vertical connection line 1820 may be electrically connected to the driving chip 20. Similarly, in the second corner portion, one data line DL or 1810 may be electrically connected to the horizontal connection line 1610 through a contact hole defined in the third interlayer-insulating layer 121, and, in a pixel located in the −x direction from the first corner portion, the horizontal connection line 1610 may be electrically connected to the vertical connection line 1820 through a contact hole defined in the third interlayer-insulating layer 121 and the vertical connection line 1820 may be electrically connected to the driving chip 20. The horizontal connection line 1610 and/or the vertical connection line 1820, which are electrically connected to the data line DL or 1810 and used to transmit data signals, may have discontinuous points at appropriate positions, thereby preventing a data signal from the driving chip 20 from being applied to an inappropriate pixel.

In this way, the horizontal connection line 1610 and the vertical connection line 1820 used to transmit data signals are located in the first corner portion or the second corner portion. Accordingly, the horizontal connection lines 1610 as shown in FIGS. 2 to 4 are not located in the first corner portion or the second corner portion and are not electrically connected to the driving chip 20.

The driving voltage line 1830 may extend substantially in the first direction (the y-axis direction). The driving voltage line 1830 may correspond to the driving voltage line PL in FIG. 5. The driving voltage line 1830 may apply the driving voltage ELVDD to the pixels. The driving voltage line 1830 may be electrically connected to the fifth transmission line 1660 through a contact hole 1830CNT, and thus, as described above, the driving voltage ELVDD may be transmitted to the operation control transistor T5 and the capacitor upper electrode 1330. The driving voltage line 1830 of the first pixel circuit PC1 may be formed integrally with the driving voltage line 1830 of the second pixel circuit PC2 adjacent thereto. The tenth transmission line 1840 may be electrically connected to the sixth transmission line 1670 through a contact hole 1840CNT1 and receive the driving current or the second initialization voltage Vint2 from the first semiconductor layer 1100 through the sixth transmission line 1670. The tenth transmission line 1840 may be configured to transmit the driving current or the second initialization voltage Vint2 from the first semiconductor layer 1100 to the main pixel electrode 310 of the organic light-emitting diode OLED through a contact hole 1840CNT2 defined in an insulating layer disposed over the tenth transmission line 1840.

For reference, as described above with reference to FIG. 4, the extension line 1911 electrically connected to the first auxiliary pixel electrode 311r for red and the second auxiliary pixel electrode 312r for red may be electrically connected to a pixel circuit disposed under a main pixel electrode for red adjacent to the auxiliary display area ADA from among the main pixel electrodes 310 located in the main display area MDA. For example, when the first pixel P1 is a red pixel located adjacent to the auxiliary display area ADA from among the red pixels located in the main display area MDA, the extension line 1911 electrically connected to the first auxiliary pixel electrode 311r for red and the second auxiliary pixel electrode 312r for red may be electrically connected to the tenth transmission line 1840 of the first pixel P1 through a contact hole defined in the fourth interlayer-insulating layer 123. Accordingly, an electrical signal that is the same as or similar to the electrical signal applied to the main pixel electrode 310 of the first pixel P1 may also be applied to the first auxiliary pixel electrode 311r for red and the second auxiliary pixel electrode 312r for red.

The second connection electrode layer 1800 may include a metal, an alloy, a conductive metal oxide, a transparent conductive material, or the like. For example, the second connection electrode layer 1800 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The second connection electrode layer 1800 may have a multi-layer structure, such as a two-layer structure of a Ti layer and an Al layer, or a three-layer structure of a Ti layer, an Al layer, and another Ti layer.

A planarization layer 125 shown in FIG. 14 may be disposed on the fourth interlayer-insulating layer 123 and cover the second connection electrode layer 1800. The fourth interlayer-insulating layer 123 may include silicon oxide, silicon nitride, silicon oxynitride, or aluminum oxide. In another embodiment, the fourth interlayer-insulating layer 123 may include an organic insulating material. For example, the fourth interlayer-insulating layer 123 may include photoresist, BCB, polyimide, HMDSO, PMMA, polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any blends thereof.

The planarization layer 125 may be disposed on the fourth interlayer-insulating layer 123. The planarization layer 125 may include an organic insulating material. For example, the planarization layer 125 may include BCB, polyimide, HMDSO, PMMA, polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any blends thereof.

As shown in FIG. 14, an organic light-emitting diode OLED may be disposed on the planarization layer 125. The organic light-emitting diode OLED may include a main pixel electrode 310, an intermediate layer 320 including an emission layer, and a common electrode 330.

The main pixel electrode 310 may include a (semi-) light-transmitting electrode or a reflective electrode. For example, the main pixel electrode 310 may include a reflective layer and a transparent or semi-transparent electrode layer disposed on the reflective layer, the reflective layer including Ag, magnesium (Mg), Al, Pt, palladium (Pd), gold (Au), Ni, neodymium (Nd), iridium (Ir), Cr, or a compound thereof. The transparent or semi-transparent electrode layer may include at least one selected from the group consisting of indium tin oxide (ITO), indium zinc oxide (IZO), zinc oxide (ZnO or ZnO₂), indium oxide (In₂O₃), indium gallium oxide (IGO), and aluminum zinc oxide (AZO). For example, the main pixel electrode 310 may have a three-layer structure of an ITO layer, an Ag layer, and another ITO layer.

A pixel-defining layer 127 may be disposed on the planarization layer 125. The pixel-defining layer 127 may prevent an arc or the like from occurring at the edge of the main pixel electrode 310 by increasing a distance between the edge of the main pixel electrode 310 and the common electrode 330 above the main pixel electrode 310.

The pixel-defining layer 127 may include one or more organic insulating materials selected from the group consisting of polyimide, polyamide, an acryl-based resin, BCB, and a phenolic resin, and may be formed by a method such as spin coating.

At least a portion of the intermediate layer 320 of the organic light-emitting diode OLED may be located within an opening OP defined by the pixel-defining layer 127. An emission area EA of the organic light-emitting diode OLED may be defined by the opening OP.

The intermediate layer 320 may include an emission layer. The emission layer may include an organic material including a fluorescent or phosphorous material emitting red, green, blue, or white light. The emission layer may include a low-molecular weight organic material or a polymer organic material, and a functional layer, such as a hole transport layer (HTL), a hole injection layer (HIL), an electron transport layer (ETL), or an electron injection layer (EIL), may selectively be further disposed under and/or over the emission layer.

The emission layer may have a patterned shape to correspond to each of the main pixel electrodes 310. A layer included in the intermediate layer 320 except for the emission layer may be integrally formed as a single body over a plurality of main pixel electrodes 310, and various modifications may be made.

The common electrode 330 may be a light-transmitting electrode or a reflective electrode. For example, the common electrode 330 may be a transparent or semi-transparent electrode and may include lithium (Li), calcium (Ca), lithium fluoride (LiF), Al, Ag, Mg, or a compound thereof. In addition, the common electrode 330 may further include a transparent conductive oxide (TCO) layer, which may include ITO, IZO, ZnO, ZnO₂, In₂O₃, or the like. The common electrode 330 may be integrally formed as a single body throughout the entire surface of the display area DA and may be disposed over the intermediate layer 320 and the pixel-defining layer 127.

The organic light-emitting diode OLED may be covered with a thin-film encapsulation layer (not shown) or a sealing substrate. In an embodiment, the thin-film encapsulation layer may include at least one inorganic encapsulation layer and at least one organic encapsulation layer. For example, the thin-film encapsulation layer may include a first inorganic encapsulation layer, a second inorganic encapsulation layer, and an organic encapsulation layer therebetween.

The first inorganic encapsulation layer and the second inorganic encapsulation layer may each include one or more inorganic insulating materials, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂), and may be formed by chemical vapor deposition (CVD) or the like. The organic encapsulation layer may include a polymer-based material. Examples of the polymer-based material may include silicone-based resin, acrylic resin (e.g., polymethyl methacrylate or polyacrylic acid), epoxy-based resin, polyimide, and polyethylene.

Each of the first inorganic encapsulation layer, the organic encapsulation layer, and the second inorganic encapsulation layer may be integrally formed as a single body to cover the display area DA.

In another embodiment, a bottom metal layer may be disposed under the first pixel circuit PC1 and the second pixel circuit PC2. The bottom metal layer may be arranged between the first and second pixel circuits PC1 and PC2 and the substrate 100 to overlap the first and second pixel circuits PC1 and PC2 in a plan view to protect the first and second pixel circuits PC1 and PC2. The bottom metal layer may prevent or reduce external light or an electric field formed in the substrate 100 from reaching and affecting the first pixel circuit PC1 and the second pixel circuit PC2.

In this way, the thin-film transistors and capacitor of a pixel circuit as shown in FIG. 5 may be formed in the main display area MDA by using the components shown in FIGS. 7 to 12. Accordingly, the thin-film transistors and/or capacitor included in the scan driver SD located in the auxiliary display area ADA and/or the peripheral area PA may also be simultaneously formed with the same material when the components as shown in FIGS. 7 to 12 are formed.

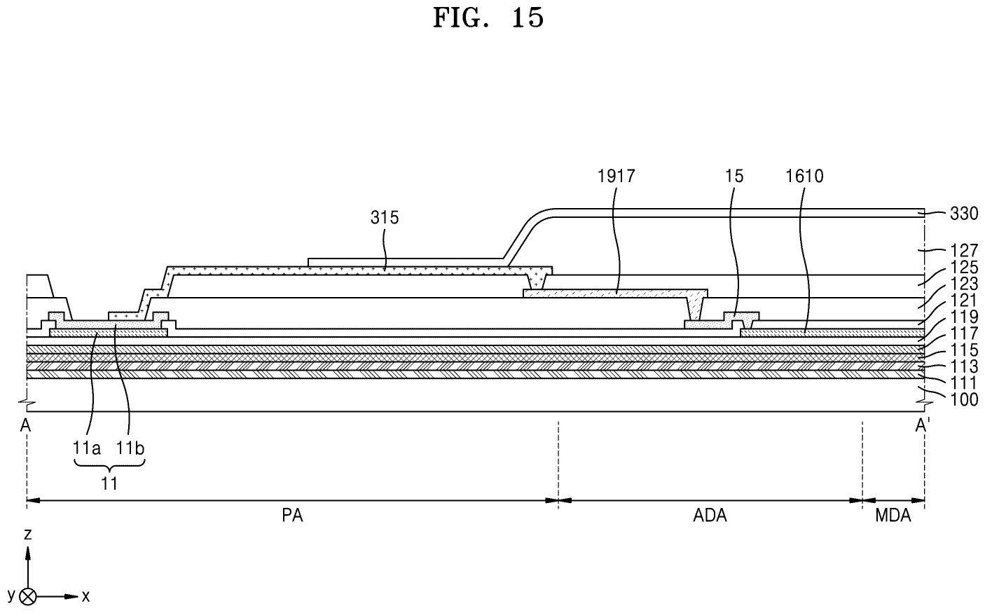

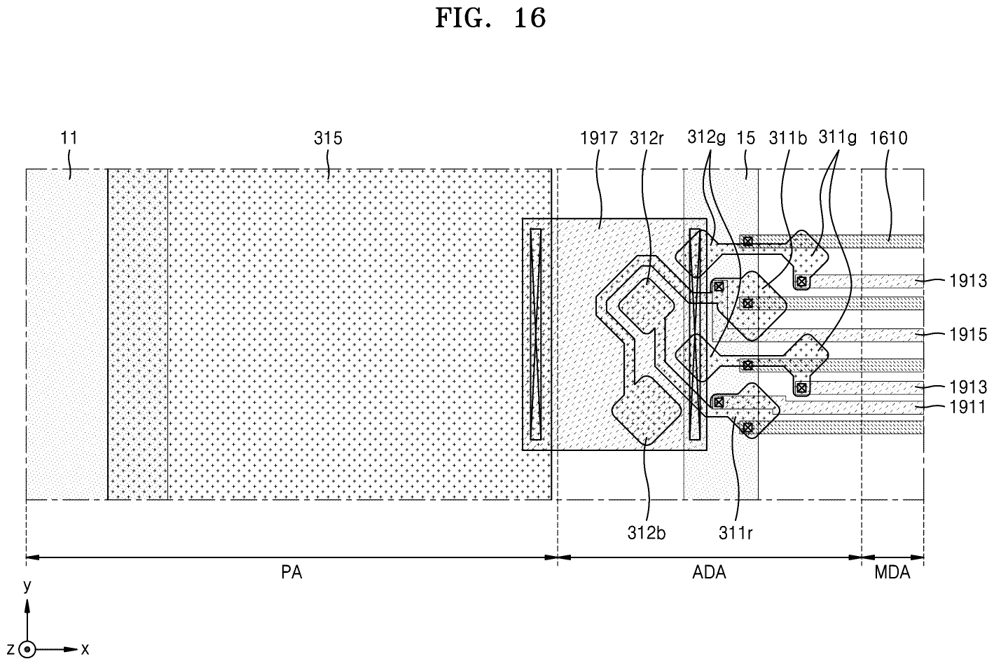

FIG. 15 is a schematic cross-sectional view illustrating a portion of a display apparatus according to an embodiment, and FIG. 16 is a schematic plan view illustrating a portion of the display apparatus of FIG. 15. Hereinafter, for convenience, only differences from the display apparatus according to the embodiment described above with reference to FIGS. 2 to 4 will be described. Therefore, the description of the display apparatus according to the embodiment described above with reference to FIGS. 2 to 4 may also apply to other parts.

In the case of the display apparatus according to the embodiment described above with reference to FIGS. 2 to 4, the connection line 315 includes a protrusion 315P that protrudes into the auxiliary display area ADA. However, in the case of the display apparatus according to the present embodiment, the connection line 315 does not have such a protrusion. Instead, the display apparatus according to the present embodiment may further include an additional connection line 1917.

The additional connection line 1917 may be located between the fourth interlayer-insulating layer 123 and the planarization layer 125, similar to the extension lines 1911, 1913, and 1915. The end of the connection line 315 in a direction toward the main display area MDA, the connection line 315 being disposed on the planarization layer 125, may contact the additional connection line 1917 through a contact hole defined in the planarization layer 125. The additional connection line 1917 may extend from the peripheral area PA to the auxiliary display area ADA. The end of the additional connection line 1917 in the direction toward the main display area MDA may be connected to the contact line 15 disposed under the additional connection line 1917 through a contact hole defined in the fourth interlayer-insulating layer 123. Accordingly, the contact line 15 may be electrically connected to the common voltage supply line 11.

A plurality of horizontal connection lines 1610 starting from the auxiliary display area ADA and extending in the second direction (the x-axis direction) to cross the main display area MDA may be disposed on the second interlayer-insulating layer 119, as described above. Each of the plurality of horizontal connection lines 1610 may be electrically connected to the additional connection line 1917. It is illustrated in FIGS. 15 and 16 that a contact line 15 disposed on the third interlayer-insulating layer 121 located in the auxiliary display area ADA and covering the horizontal connection lines 1610 contacts the horizontal connection lines 1610 through contact holes defined in the third interlayer-insulating layer 121. Accordingly, each of the plurality of horizontal connection lines 1610 may be electrically connected to the additional connection line 1917 through the contact line 15 and thus may be electrically connected to the common voltage supply line 11.

As described above, the end of the connection line 315 in the direction toward the main display area MDA may contact the additional connection line 1917 through a contact hole defined in the planarization layer 125. In this case, the contact hole defined in the planarization layer 125 may extend in the first direction (the y-axis direction), as shown in FIG. 16, to increase the contact area between the connection line 315 and the additional connection line 1917, thereby lowering the contact resistance therebetween. In addition, as described above, the end of the additional connection line 1917 in the direction toward the main display area MDA may be connected to the contact line disposed under the additional connection line 1917 through a contact hole defined in the fourth interlayer-insulating layer 123. The contact hole defined in the fourth interlayer-insulating layer 123 may extend in the first direction (the y-axis direction), as shown in FIG. 16, to increase the contact area between the additional connection line 1917 and the contact line 15, thereby lowering the contact resistance therebetween.

The additional connection line 1917 and the extension lines 1911, 1913, and 1915, which are located between the fourth interlayer-insulating layer 123 and the planarization layer 125, may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The additional connection line 1917 and the extension lines 1911, 1913, and 1915 may each have a multi-layer structure, such as a two-layer structure of a Ti layer and an Al layer, or a three-layer structure of a Ti layer, an Al layer, and another Ti layer.

Even in the case of the display apparatus according to the present embodiment, at least a portion of the scan driver SD may overlap the auxiliary display area ADA when viewed in the direction (the z-axis direction) perpendicular to the substrate 100 (i.e., in a plan view).

The scan driver SD may include a thin-film transistor and/or a capacitor, and the pixel circuit located in the main display area MDA may also include a thin-film transistor and/or a capacitor. Therefore, during a manufacturing process, the thin-film transistor and/or capacitor included in the scan driver SD may be directly formed on the same layer as, of the same material as, and simultaneously with the thin-film transistor and/or capacitor included in the pixel circuit located in the main display area MDA when the thin-film transistor and/or capacitor included in the pixel circuit are formed.

As described above, unlike the main display area MDA, there is no pixel circuit in the auxiliary display area ADA, and thus, at least a portion of the scan driver SD may be located in the auxiliary display area ADA. Accordingly, the overall display area of the display apparatus may be increased by using the main display area MDA and the auxiliary display area ADA, while the area of the peripheral area PA for the scan driver SD to be located may be relatively reduced. In another embodiment, a portion of the scan driver SD may be disposed under the connection line 315. In this case, the connection line 315 may function as a shield layer that protects the scan driver SD from external static electricity or the like.

It may be considered to omit the connection line 315 and have the additional connection line 1917 extend toward the edge of the substrate 100 to contact the common voltage supply line 11. However, in this case, the quality of the image displayed by the display apparatus may deteriorate due to parasitic capacitance between some components of the scan driver SD and the additional connection line 1917.

As described above with reference to FIG. 1, there is a clock signal line CKL on the substrate 100, and this clock signal line CKL may extend into the scan driver SD and provide a clock signal to the thin-film transistor and the like included in the scan driver SD. From this perspective, it may be said that the scan driver SD includes a clock signal line CKL, and the clock signal line CKL may have a shape extending in the first direction (the y-axis direction) along a portion of the common voltage supply line 11. The distance between the clock signal line CKL and other conductive layers is desirable to be kept as long as possible to ensure that a high-quality image is to be displayed. However, if the connection line 315 is omitted and instead the additional connection line 1917 extends toward the edge of the substrate 100 to contact the common voltage supply line 11, the clock signal line CKL is disposed under the additional connection line 1917 in the peripheral area PA, and accordingly, the quality of the image displayed by the display apparatus may deteriorate due to the short distance between the clock signal line CKL and the additional connection line 1917. Therefore, in an embodiment, the connection line 315 may be present in the peripheral area PA and the clock signal line CKL may be disposed under the connection line 315, and thus, a sufficient distance between the clock signal line CKL and the connection line 315 may be maintained compared to a case that the additional connection line 1917 disposed on a lower layer is substituted for the connection line 315 disposed on a higher layer, thereby implementing a display apparatus that displays a high-quality image.

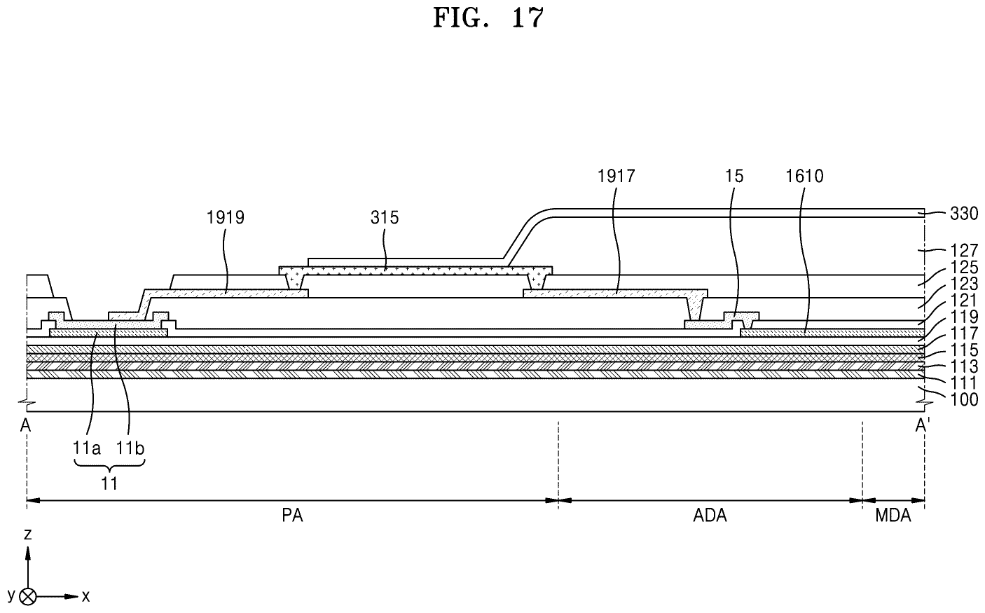

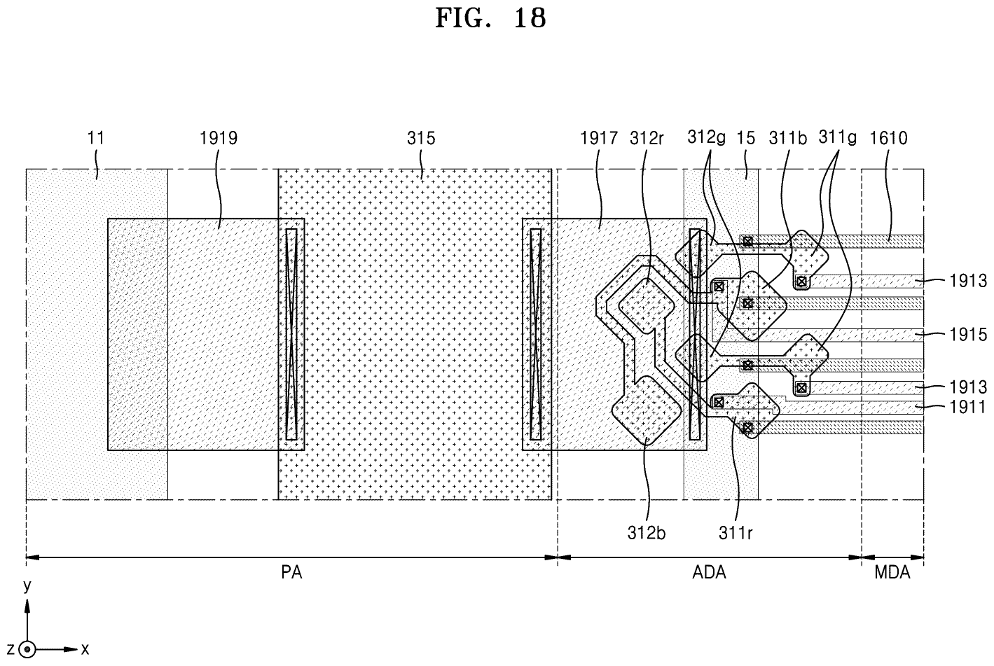

FIG. 17 is a schematic cross-sectional view illustrating a portion of a display apparatus according to an embodiment, and FIG. 18 is a schematic plan view illustrating a portion of the display apparatus of FIG. 17. The difference between the display apparatus according to the present embodiment and the display apparatus described above with reference to FIGS. 15 and 16 is that, in the display apparatus according to the present embodiment, the connection line 315 does not directly contact the common voltage supply line 11 and an auxiliary connection line 1919 that contacts the common voltage supply line 11 and the connection line 315 and electrically connects the common voltage supply line 11 to the connection line 315 is further provided. The auxiliary connection line 1919 may be directly formed on the same layer as, of the same material as, and simultaneously with the additional connection line 1917. Accordingly, the auxiliary connection line 1919 may have, for example, a two-layer structure of a Ti layer and an Al layer, or a three-layer structure of a Ti layer, an Al layer, and another Ti layer so that the conductivity of the auxiliary connection line 1919 is higher than a conductivity of the connection line 315, and thus, the overall resistance from the common voltage supply line 11 to the horizontal connection lines 1610 may be lowered.

Even in this case, the clock signal line CKL included in the scan driver SD may be disposed under the connection line 315, that is, the clock signal line CKL may overlap the connection line 315 when viewed in the direction (the z-axis direction) perpendicular to the substrate 100 (i.e., in a plan view), and thus, a display apparatus capable of displaying a high-quality image may be implemented.

In the case of the display apparatus according to embodiments, a portion of the scan driver SD may be located in the auxiliary display area ADA, and thus, the overall display area of the display apparatus may be increased by using the main display area MDA and the auxiliary display area ADA, while the area of the peripheral area PA for the scan driver SD to be located may be relatively reduced. However, the disclosure is not limited to this. For example, the descriptions given above may be applied as is to an emission control driver other than a scan driver SD. For example, even when an emission control driver is located near the second edge E2 of the substrate 100, as described above with reference to FIG. 1, the above descriptions of the scan driver SD may be applied to the emission control driver. In this regard, in the descriptions of the embodiments described above, the scan driver SD may be referred to as a ‘driver circuit’.

According to one or more embodiments as described above, a display apparatus in which the area of a display area is expanded and which is capable of displaying a high-quality image may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including a main display area, an auxiliary display area outside the main display area, and a peripheral area outside the auxiliary display area;
a common voltage supply line located in the peripheral area;
a connection line contacting the common voltage supply line and having a protrusion protruding into the auxiliary display area;
a pixel circuit located in the main display area;
a main pixel electrode located in the main display area and electrically connected to the pixel circuit;
a first auxiliary pixel electrode and a second auxiliary pixel electrode located in the auxiliary display area and electrically connected to each other;
an extension line electrically connecting any one of the first auxiliary pixel electrode and the second auxiliary pixel electrode to the pixel circuit; and
a driver circuit, which at least partially overlaps the auxiliary display area in a plan view.

2. The display apparatus of claim 1, further comprising a plurality of horizontal connection lines extending across the main display area and electrically connected to the protrusion of the connection line.

3. The display apparatus of claim 2, further comprising a contact line located in the auxiliary display area,
wherein the contact line is disposed under the protrusion of the connection line and contacts the protrusion of the connection line, and
wherein the plurality of horizontal connection lines contact the contact line.

4. The display apparatus of claim 3, wherein the connection line is directly disposed on a same layer as the first auxiliary pixel electrode, the second auxiliary pixel electrode, and the main pixel electrode, and the plurality of horizontal connection lines are disposed under the contact line and contact the contact line.

5. The display apparatus of claim 3, wherein the common voltage supply line extends along an edge of the substrate, the contact line extends along at least a portion of the common voltage supply line, and the plurality of horizontal connection lines extend in a direction crossing a direction in which the contact line extends.

6. The display apparatus of claim 3, wherein the extension line is disposed on a first insulating layer covering the contact line, and the first auxiliary pixel electrode, the second auxiliary pixel electrode, the main pixel electrode, and the connection line are disposed on a second insulating layer covering the extension line.

7. The display apparatus of claim 6, wherein the extension line includes a transparent conductive layer.

8. The display apparatus of claim 1, wherein the first auxiliary pixel electrode and the second auxiliary pixel electrode are integrally formed as a single body.

9. The display apparatus of claim 1, wherein the driver circuit is disposed under the first auxiliary pixel electrode and the second auxiliary pixel electrode and under the connection line.

10. A display apparatus comprising:
a substrate including a main display area, an auxiliary display area outside the main display area, and a peripheral area outside the auxiliary display area;
a common voltage supply line located in the peripheral area;
a connection line electrically connected to the common voltage supply line and located in the peripheral area;
an additional connection line having one side contacting the connection line, the additional connection line extending into the auxiliary display area;
a pixel circuit located in the main display area;
a main pixel electrode located in the main display area and electrically connected to the pixel circuit;
a first auxiliary pixel electrode and a second auxiliary pixel electrode located in the auxiliary display area and electrically connected to each other;
an extension line electrically connecting any one of the first auxiliary pixel electrode and the second auxiliary pixel electrode to the pixel circuit; and
a driver circuit, which at least partially overlaps the auxiliary display area in a plan view.

11. The display apparatus of claim 10, further comprising a plurality of horizontal connection lines extending across the main display area and electrically connected to the additional connection line.

12. The display apparatus of claim 11, further comprising a contact line located in the auxiliary display area,
wherein the contact line is disposed under the additional connection line and contacts the additional connection line, and
wherein the plurality of horizontal connection lines contact the contact line.

13. The display apparatus of claim 12, wherein the connection line is directly disposed on a same layer as the first auxiliary pixel electrode, the second auxiliary pixel electrode, and the main pixel electrode, and the plurality of horizontal connection lines are disposed under the contact line and contact the contact line.

14. The display apparatus of claim 12, wherein the common voltage supply line extends along an edge of the substrate, the contact line extends along at least a portion of the common voltage supply line, and the plurality of horizontal connection lines extend in a direction crossing a direction in which the contact line extends.

15. The display apparatus of claim 12, wherein the extension line is disposed on a first insulating layer covering the contact line, and the first auxiliary pixel electrode, the second auxiliary pixel electrode, the main pixel electrode, and the connection line are disposed on a second insulating layer covering the extension line.

16. The display apparatus of claim 10, wherein the first auxiliary pixel electrode and the second auxiliary pixel electrode are integrally formed as a single body.

17. The display apparatus of claim 10, wherein the driver circuit is disposed under the first auxiliary pixel electrode and the second auxiliary pixel electrode and under the connection line.

18. The display apparatus of claim 10, wherein the driver circuit is connected to a clock signal line disposed under the connection line.

19. The display apparatus of claim 18, wherein the common voltage supply line extends along an edge of the substrate, and each of the connection line and the clock signal line extends along a portion of the common voltage supply line.

20. The display apparatus of claim 10, wherein the connection line contacts the common voltage supply line.

21. The display apparatus of claim 10, further comprising an auxiliary connection line, which contacts the common voltage supply line and the connection line and electrically connects the common voltage supply line to the connection line.

22. The display apparatus of claim 21, wherein the auxiliary connection line and the additional connection line are directly disposed on a same layer.
